(19) United States
(12) Patent Application Publication
(10) Pub. No.: US 2023/0022002 A1
(43) Pub. Date: Jan. 26, 2023

(54) IONIC SALT, RADIATION-SENSITIVE RESIST COMPOSITION COMPRISING THE SAME, AND METHOD OF FORMING PATTERN USING THE SAME

(71) Applicants: Samsung Electronics Co., Ltd., Suwon-si (KR); THE UNIVERSITY OF TOKYO, Tokyo (JP)

(72) Inventors: Sayaka UCHIDA, Tokyo (JP); Naoki OGIWARA, Tokyo (JP); Mitsumasa HAMANO, Kanagawa (JP); Tadao YAGI, Hwaseong-si (KR); Nobuji SAKAI, Kanagawa (JP)

(73) Assignees: Samsung Electronics Co., Ltd., Suwon-si (KR); THE UNIVERSITY OF TOKYO, Tokyo (JP)

(21) Appl. No.: 17/865,936

(22) Filed: Jul. 15, 2022

(30) Foreign Application Priority Data
Jul. 16, 2021 (JP) 2021-117851
Jul. 4, 2022 (KR) 10-2022-0082141

(51) Int. Cl. G03F 7/004; C01B 21/38

(52) U.S. Cl. CPC G03F 7/0042; C01B 21/38

(57) ABSTRACT

An ionic salt includes a polyvalent ion (a) having a metal cluster structure or a metal oxide cluster structure and an organic ion (b), a radiation-sensitive resist composition including the ionic salt, and a pattern forming method, wherein the polyvalent ion (a) includes at least one metal atom selected from the group consisting of tin, indium, antimony, tellurium, and bismuth, and the organic ion (b) is at least one selected from the group consisting of: a carboxylate anion having 4 or more carbon atoms; a sulfonate anion having 4 or more carbon atoms; a phosphonate anion having 4 or more carbon atoms; a phenoxide anion having 6 or more carbon atoms; an iodonium cation having 4 or more carbon atoms; a sulfonium cation having 4 or more carbon atoms; an ammonium cation having 4 or more carbon atoms; and a pyridinium cation having 5 or more carbon atoms.

### CROSS-REFERENCE TO RELATED APPLICATION

This application is based on and claims priority under 35 U.S.C. § 119 to Japanese Patent Application No. 2021-117851, filed on Jul. 16, 2021, in the Japanese Patent Office, and Korean Patent Application No. 2022-0082141, filed on Jul. 4, 2022 in the Korean Intellectual Property Office the disclosures of each of which are incorporated herein in their entirety by reference.

### BACKGROUND

There is a constant demand for miniaturization of semiconductor processing, which leads to high speed and low power consumption of semiconductor chips, and research and development of lithography technology, which is the center of such miniaturization, is in progress. In recent years, as the light source for lithography has been shifted to extreme ultraviolet (EUV), it has become possible to obtain resist patterns with a linewidth of 20 nm or less. Chemically amplified resists used to obtain such resist patterns may have superior sensitivity and/or resolution as compared to materials for excimer laser that have been used so far.

However, to obtain desired resist patterns having a linewidth of 10 nm or less, it is necessary or desirable to improve both the sensitivity and resolution of chemically amplified resists. In particular, there is a need or desire to help resolve issues of low EUV absorbance with organic materials included in chemically amplified resists.

### SUMMARY

Some example embodiments provide an ionic salt having characteristics including improved radiation (EUV in particular) absorbance, improved sensitivity, improved development properties and/or improved resolution, a radiation-sensitive resist composition including the ionic salt, and/or a pattern forming method using the radiation-sensitive resist composition.

Additional aspects will be set forth in part in the description which follows and, in part, will be apparent from the description, or may be learned by practice of various example embodiments.

According to some example embodiments, the ionic salt is or includes an ionic salt composed of a polyvalent ion (a) having a metal cluster structure or a metal oxide cluster structure, and an organic ion (b), wherein the polyvalent ion (a) comprises at least one metal atom selected from the group consisting of tin, indium, antimony, tellurium, and bismuth, and the organic ion (b) is at least one selected from the group consisting of a carboxylate anion having 4 or more carbon atoms; a sulfonate anion having 4 or more carbon atoms; a phosphonate anion having 4 or more carbon atoms; a phenoxide anion having 6 or more carbon atoms; an iodonium cation having 4 or more carbon atoms; a sulfonium cation having 4 or more carbon atoms; an ammonium cation having 4 or more carbon atoms; and a pyridinium cation having 5 or more carbon atoms.

According to some example embodiments, the radiation-sensitive resist composition includes the ionic salt and an organic solvent.

According to some example embodiments, a pattern forming method includes: forming a resist film by coating the radiation-sensitive resist composition onto a substrate; exposing the resist film; and developing the exposed resist film.

### BRIEF DESCRIPTION OF THE DRAWINGS

The above and other aspects, features, and advantages of certain embodiments will be more apparent from the following description taken in conjunction with the accompanying drawings, in which:

FIG. 1A shows an X-ray power diffraction pattern of Compound 1 obtained in Synthesis Example 1;

FIG. 1B shows a Fourier transform infrared spectroscopy (FT-IR) spectrum of Compound 1 obtained in Synthesis Example 1;

FIG. 2A shows an X-ray power diffraction pattern of Compound 2 obtained in Synthesis Example 2;

FIG. 2B shows an FT-IR spectrum of Compound 2 obtained in Synthesis Example 2;

FIG. 3 shows an FT-IR spectrum of Compound 3 obtained in Synthesis Example 3;

FIG. 4 shows an FT-IR spectrum of Compound 4 obtained in Synthesis Example 4;

FIG. 5 shows an FT-IR spectrum of Compound 5 obtained in Synthesis Example 5;

FIG. 6 shows an FT-IR spectrum of Compound 6 obtained in Synthesis Example 6;

FIG. 7 shows an FT-IR spectrum of Compound 7 obtained in Synthesis Example 7;

FIG. 8 shows an FT-IR spectrum of Compound 8 obtained in Synthesis Example 8;

FIG. 9 shows an FT-IR spectrum of Compound 9 obtained in Synthesis Example 9;

FIG. 10 shows an FT-IR spectrum of Compound 10 obtained in Synthesis Example 10;

FIG. 11 shows an FT-IR spectrum of Compound 11 obtained in Synthesis Example 11;

FIG. 12 shows an FT-IR spectrum of Compound 12 obtained in Synthesis Example 12;

FIG. 13 shows an FT-IR spectrum of Compound 13 obtained in Synthesis Example 13;

FIG. 14 shows an FT-IR spectrum of Compound 14 obtained in Synthesis Example 14;

FIG. 15 shows an FT-IR spectrum of Compound 15 obtained in Synthesis Example 15;

FIG. 16 shows an FT-IR spectrum of Compound 16 obtained in Synthesis Example 16;

FIG. 17 shows an FT-IR spectrum of Compound 17 obtained in Synthesis Example 17;

FIG. 18 shows an FT-IR spectrum of Compound 18 obtained in Synthesis Example 18;

FIG. 19 shows an FT-IR spectrum of Compound 19 obtained in Synthesis Example 19;

FIG. 20 shows an FT-IR spectrum of Compound 20 obtained in Synthesis Example 20; and

FIG. 21 shows a method of forming a pattern on a substrate.

### DETAILED DESCRIPTION

Reference will now be made in detail to various embodiments, examples of which are illustrated in the accompanying drawings, wherein like reference numerals refer to like elements throughout. In this regard, the present embodiments may have different forms and should not be construed as being limited to the descriptions set forth herein. Accordingly, variously described example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Some example embodiments include an ionic salt composed of a polyvalent ion (a) having a metal cluster structure or a metal oxide cluster structure, and an organic ion (b). The polyvalent ion (a) and the organic ion (b) are bound by ionic bonds and form a salt.

The polyvalent ion (a) includes at least one metal atoms selected from the group consisting of tin, indium, antimony, tellurium, and bismuth. In addition, the organic ion (b) may be at least one selected from the group consisting of: a carboxylate anion having 4 or more carbon atoms; a sulfonate anion having 4 or more carbon atoms; a phosphonate anion having 4 or more carbon atoms; a phenoxide anion having 6 or more carbon atoms; an iodonium cation having 4 or more carbon atoms; a sulfonium cation having 4 or more carbon atoms; an ammonium cation having 4 or more carbon atoms; and a pyridinium cation having 5 or more carbon atoms.

The ionic salt has characteristics including improved radiation (EUV in particular) absorption properties, improved sensitivity, improved development properties, and improved resolution.

The polyvalent ion (a) includes at least one metal atom selected from the group consisting of tin, indium, antimony, tellurium, and bismuth. Since such metal atoms have a high radiation absorbance coefficient, especially in the EUV range, and release secondary electrons efficiently, the sensitivity of the ionic salt may be improved. In particular, a resist material including such metal atoms may provide improved sensitivity and/or resolution as compared to resist materials that include organic materials having carbon atoms or oxygen atoms as the main components.

Alternatively or additionally, polyvalency of the polyvalent ion (a) allows a wide range of structural designs of the organic ion (b), which serves as a counter ion, and facilitates an improvement in sensitivity, development properties, resolution, and the like. Alternatively or additionally, such polyvalency leads to increased repulsion between polyvalent ions (a), and thus can lead to improved dispersion in solution. Accordingly, when a resist film is formed from coating a resist composition including the above ionic salt, the resist film may have improved uniformity and may provide improved development properties and/or resolution.

Alternatively or additionally, the organic ion (b) has a structure that efficiently undergoes chemical reactions, such as a polarity change reaction and a crosslinking reaction, with secondary electrons released from the polyvalent ion (a) by radiation. The ionic salt including such an organic ion (b) may provide improved sensitivity, development properties, and/or resolution, and the like.

Hereinbelow, the ionic salt will be described in greater detail.

[Ionic Salt]

<Polyvalent Ion (a)>

The ionic salt has a polyvalent ion (a) including a metal cluster or a metal oxide cluster. Here, the term “metal cluster” refers to a cluster of compounds containing metal atoms, having a uniform structural unit through bonds between the metal atoms. The term “metal oxide cluster” refers to an atomic cluster, a molecular cluster, or a cluster formed by bonds between atoms or molecules of different kinds that constitute a metal oxide. By having such a cluster structure, the polyvalent ion (a) may have a reduced size, and when used in resists, may provide improved resolution.

The polyvalent ion (a) includes one or more metal atoms selected from the group consisting of tin, indium, antimony, tellurium, and bismuth. In the interest of improving radiation (EUV in particular) absorption properties, the polyvalent ion (a) may include one or more metal atoms selected from the group consisting of indium, antimony, tellurium, and bismuth.

The total number of metal atoms in the polyvalent ion (a) may be in a range of 4 to 30, and more specifically, in a range of 4 to 20. Once the above range is satisfied or at least partially satisfied, the polyvalent ion (a) may have a further reduced size and/or may provide a further improved resolution.

With respect to 100 at % of the total number of metal atoms in the polyvalent ion (a), the content of one or more metal atoms selected from the group consisting of tin, indium, antimony, tellurium, and bismuth, may be about 50 at % or more. Once the above range is satisfied, there are relatively more metal atoms with a high absorption coefficient with respect to radiation (EUV in particular), and thus, sensitivity to radiation (EUV in particular) may be further improved. In particular, with respect to 100 at % of the total number of metal atoms in the polyvalent ion (a), the content of one or more metal atoms selected from the group consisting of tin, indium, antimony, tellurium, and bismuth, may be about 70 at % or more and may be 100 at % at maximum.

The polyvalent ion (a) may have a molecular weight of about 600 or more to about 9,000 or less, and more specifically, may have a molecular weight of about 1,000 or more to about 6,000 or less. Once the above range is at least partially satisfied, the polyvalent ion (a) may have a further reduced size and/or may provide a further improved resolution. Also, in the present specification, a molecular weight means the sum of atomic weights of atoms constituting an ion or a compound.

The polyvalent ion (a) may have a valency of 3 or more, and specifically, a valency of 3 or more to 10 or less. Once the above range is satisfied, the resist film may have a further improved film uniformity and may have further improved sensitivity, development properties, resolution, and/or the like.

In the interest of further improving the resolution, the polyvalent ion (a) may have an average diameter of about 10 nm or less, and more specifically, about 3 nm or less. Also, the polyvalent ion (a) may have an average diameter of about 0.5 nm or more. The average diameter may be measured by methods such as single-crystal X-ray structural analysis, dynamic light scattering analysis of solution, and/or the like.

The polyvalent ion (a) may be anionic, or may be cationic. Alternatively or additionally, the polyvalent ion (a) may be a single type of polyvalent ion, or a combination of two or more polyvalent ions.

In some example embodiments, the polyvalent ion (a) may be one or more selected from the group consisting of [Sn₈W₁₈O₆₆]⁸⁻, [Sn₄W₂Si₂O₆₈]¹⁴⁻, [Sn₃W₁₈Si₂O₆₈]¹⁴⁻, [Sn₃W₁₈P₂O₆₈]¹²⁻, [SnW₁₂H₂O₄₂]⁸⁻, [W₂₈Te₁₀O₁₁₈]²⁸⁻, [W₁₈Te₂Cu₃H₆O₆₉]¹⁰⁻, [W₂₀Te₄H₂O₈₀]²²⁻, [W₂₈Te₉O₁₁₂]²⁴⁻, [W₅₈Te₂H₁₀O₁₉₈]²⁶⁻, [W₁₈TeH₃O₆₃]⁵⁻, [W₁₈TeH₃O₆₂]⁷⁻, [W₆TeO₂₄]⁶⁻, [W₁₇Te₂O₆₁]¹²⁻, [W₁₅TeNaO₅₄]¹³⁻, [Te₄C₈H₂₀]²⁺, [InW₁₁PH₄O₄₀]⁴⁻, [InW₁₁SiH₄O₄₀]⁵⁻, [InW₃O₄(C₂H₄COO)₈]²²⁻, [Sb₂I₉]⁻, [{(4-chlorophenyl)Sb}₁₂Na₂H₉O₃₀]⁻, [(SbW₉O₃₃)₂{Nb(C₂H₄)}₂]¹²⁻, [Mo₂Te₁₂]⁶⁺, [NbTe₁₀]³⁻, [Ru₆(Te₂)₇(CO)₁₂]²⁻, [(SbW₉O₃₃)₂{Nb(C₂H₄)}₂]¹²⁻, [MoTe₈O]²⁺, [Bi₆(CH₃OH)₂(NO₃)₃(OH₂)₂(Sha_{-1H})₁₂]²⁺, [Bi₆O₄(OH)₄(H₂O)₆]²⁺, [Bi₆O₄(OH)₄(NO₃)₅(H₂O)]⁺, [Bi₆O₄OH(cit)₃(H₂O)₃]³⁻, [Pr₄Sb₁₂O₁₈Cl₁₇]⁵⁻, [Pr₄Sb₁₂O₁₈Cl₁₄(1,3-bdc)]⁴⁻, [Pr₄Sb₁₂O₁₈Cl₁₁(1,4-bdc)₂]³⁻, [OIn₆(taci_{-3H})₄]⁴⁺, [In₃Te₇]⁵⁻, {[Bi₆O₅(OH)₃(NO₃)₃]₂}⁴⁺, [Bi₉O₈(OH)₆]⁵⁺, and [Bi₉O₈(OC₂H₄)₆]⁵⁺.

Here, Sha represents salicylhydroxamic acid, cit represents citrate, 1,3-bdc represents 1,3-benzenedicarboxylicate, 1,4-bdc represents 1,4-benzenedicarboxylicate, and taci represents 1,3,5-triamino-1,3,5-trideoxyinositol.

In particular, the polyvalent ion (a) may be one, or two or more, selected from the group consisting of [Pr₄Sb₁₂O₁₈Cl₁₇]⁵⁻, [Pr₄Sb₁₂O₁₈Cl₁₄(1,3-bdc)]⁴⁻, [Pr₄Sb₁₂O₁₈Cl₁₁(1,4-bdc)₂]³⁻, [OIn₆(taci_{-3H})₄]⁴⁺, [In₃Te₇]⁵⁻, {[Bi₆O₅(OH)₃(NO₃)₃]₂}⁴⁺, [Bi₉O₈(OH)₆]⁵⁺, and [Bi₉O₈(OC₂H₄)₆]⁵⁺.

(Preparation Process for Polyvalent Ion (a))

As a metal-containing component of a metal cluster or a metal oxide cluster included in the polyvalent ion (a), a commercially available metal-containing compound may be used. For example, hydrolysis-condensation reactions may be performed using the commercially available metal-containing compound to synthesize the metal cluster or the metal oxide cluster. Here, the term “hydrolysis-condensation reactions” refers to a reaction in which a hydrolysable group of a metal compound is hydrolyzed to form —OH groups, and then the two —OH groups thus produced are dehydrated and condensed to form —O—.

Examples of the metal-containing compound include a metal compound having a hydrolysable group, a hydrolysate of a metal compound (I) having a hydrolysable group, a hydrolysis-condensation product of a metal compound having a hydrolysable group, or a combination thereof. In addition, for the metal-containing compound, a single type of such a metal-containing compound may be used, or a combination of two or more such metal-containing compounds may be used.

More specific methods of hydrolysis-condensation reactions include examples such as a sol-gel method, hydrothermal synthesis, a glycothermal method, as well as a common sintering method and gas phase synthesis. Also, it may be a method that includes a property adjustment process for obtaining a desired range of a property by a hydrothermal process following the hydrolysis-condensation reactions.

In particular, examples of a typical structure of the metal oxide cluster may include, but are not limited to, the Keggin structure, the Wells-Dawson structure, the Anderson-Evans-Perloff structure, and the like.

<Organic Ion (b)>

In addition, the organic ion (b) has a structure that efficiently undergoes chemical reactions, such as one or more of a polarity change reaction, a crosslinking reaction, etc. with secondary electrons released from the polyvalent ion (a) by radiation. The ionic salt having such an organic ion (b) may provide improved development properties and/or resolution, and the like.

The organic ion (b) is at least one selected from the group consisting of a carboxylate anion having 4 or more carbon atoms; a sulfonate anion having 4 or more carbon atoms; a phosphonate anion having 4 or more carbon atoms; a phenoxide anion having 6 or more carbon atoms; an iodonium cation having 4 or more carbon atoms; a sulfonium cation having 4 or more carbon atoms; an ammonium cation having 4 or more carbon atoms; and a pyridinium cation having 5 or more carbon atoms.

The carboxylate anion, the sulfonate anion, the phosphonate anion, the iodonium cation, the sulfonium cation, and the ammonium cation each have 4 or more carbon atoms. When such ions have less than 4 carbon atoms, solvent solubility and photosensitivity may be reduced, and resolution and sensitivity as a resist may be diminished. The number of carbon atoms may be 6 or more, particularly, 8 or more.

The number of carbon atoms in the phenoxide anion may be 6 or more, particularly, 8 or more, and more particularly, 10 or more.

The number of carbon atoms in the pyridinium cation may be 5 or more, particularly 7 or more, and more particularly, 9 or more.

The upper limit of the number of carbon atoms in such ions is not particularly limited, but is commonly 100 or less, and may be 30 or less.

If the organic ion (b) is an ammonium cation or a pyridinium cation, such an ion may have at least one functional group selected from the group consisting of a carbon-carbon multiple bond-containing group, a carbonyl group-containing group, an oxime group, an oxime ester group, a halogenated alkyl group, a phosphorus-containing group, a diazo group, and an azide group.

“Carbon-carbon multiple bond-containing group” refers to a group that contains a double bond or a triple bond between two carbon atoms. In such double bonds, conjugated double bonds in aromatic cyclic hydrocarbons and aromatic heterocyclic compounds are included.

Examples of the carbon-carbon double bond-containing group include: ethylenic double bond-containing groups, such as a vinyl group, a vinyloxy group, an allyl group, an aryloxy group, a (meth)acryloyl group, a (meth)acryloyloxy group, a maleimide group, and the like; aromatic carbon ring-containing groups, such as a phenyl group, naphthyl group, an anthracene group, a benzoate group, a cinnamate group, an anthraquinone group, a styryl group, a stilbene group, a styrylpyridine group, a ketoprofen group, and the like; aromatic heterocyclic ring-containing groups, such as a nicotinate group, a thioxanthone group, and the like; and any of the aforementioned groups in which some or all of the hydrogen atoms are substituted with a hydroxy group, a halogen atom, a monovalent organic group, etc. (hereinafter, referred to as “substituent (a)”).

Examples of the carbon-carbon triple bond-containing group include a propargyl group, a propargyloxy group, any of the aforementioned groups in which some or all of the hydrogen atoms are substituted with a substituent (a), an ethynyl group, an ethynyloxy group, an ethynylcarbonyl group-containing group, a phenylethynylcarbonyl-containing group, and the like.

A carbonyl group-containing group refers to a group containing a carbonyl group (>C═O), and examples of the carbonyl group-containing group include an aldehyde group, a ketone group, a carboxyl group, an alkoxycarbonyl group (ester group), an amide group, an isocyanate group, a carbamate group (—OC(O)NH₂), an acid anhydride residue (—C(O)OC(O)—), an imide residue (—C(O)NHC(O)—, etc.), a carbonate group (—OC(O)O—), and the like. More specific examples of the carbonyl group-containing group include an acetophenone group, a benzophenone group, a ketoprofen group, and the like.

Examples of the oxime ester group include an oxime methyl ester, an oxime ethyl ester, and the like.

Examples of the halogenated alkyl group include a straight-chain, branched, or cyclic alkyl group having 1 to 10 carbon atoms, which has at least one hydrogen atom substituted with a halogen atom. Examples of the halogen atom in the halogenated alkyl group include a fluorine atom, a chlorine atom, a bromine atom, an iodine atom, and the like.

The phosphorus-containing group refers to a group containing at least one phosphorus atom, and examples of the phosphorus-containing group include a phosphonic acid group, a phosphinic acid group, a phosphine oxide group, a phosphonous acid group, a phosphinous acid group, a phosphine group, and the like.

Examples of the diazo group include a diazoalkane group, a diazonaphthoquinone group, and a diaziridine group.

Examples of the azide group include an azide methyl group, an azide ethyl group, and an azide aryl group.

The ammonium cation and the pyridinium cation may have the above functional groups, and another organic ion (b) may also have the above functional groups. That is, in some example embodiments, the organic ion (b) may have one or more functional groups selected from the group consisting of a carbon-carbon multiple bond-containing group, a carbonyl group-containing group, an oxime group, an oxime ester group, a halogenated alkyl group, a phosphorus-containing group, a diazo group, and an azide group.

In another embodiment, the organic ion (b) may have one or more functional groups selected from the group consisting of a vinyl group, a stilbene group, an azide group, a diazoalkane group, a diaziridine group, a cinnamate group, an anthracene group, an anthraquinone group, a maleimide group, a styrylpyridine group, an arylsulfonium group, an aryliodonium group, and a phenyl ester group.

The organic ion (b) may be a monovalent ion or a polyvalent ion with a valence of 2 or more, but in the interest of resolution, may be monovalent. In addition, the organic ion (b) may be anionic or may be cationic. In addition, for the organic ion (b) constituting the ionic salt, a single type of such an organic ion may be used, or a combination of two or more such organic ions may be used.

In particular, the organic ion (b) may be one or more selected from the group consisting of a 4-azidobenzoate anion unsubstituted or substituted with a substituent, a cinnamate anion unsubstituted or substituted with a substituent, a nicotinate anion unsubstituted or substituted with a substituent, a ketoprofen anion unsubstituted or substituted with a substituent, a 6-maleimide caproate anion (6-maleimide hexanoate anion) unsubstituted or substituted with a substituent, a 4-naphthoquinone diazide sulfonate anion unsubstituted or substituted with a substituent, a 5-naphthoquinone diazide sulfonate anion unsubstituted or substituted with a substituent, a 6-naphthoquinone diazide sulfonate anion unsubstituted or substituted with a substituent, an anthraquinone-1-sulfonate anion unsubstituted or substituted with a substituent, an anthraquinone-2-sulfonate anion unsubstituted or substituted with a substituent, a 9,10-dimethoxyanthracene-2-sulfonate anion unsubstituted or substituted with a substituent, a 4-[4-(dimethylamino)styryl]-1-methylpyridinium cation unsubstituted or substituted with a substituent, diphenyliodonium cation unsubstituted or substituted with a substituent, a triphenyl sulfonium cation unsubstituted or substituted with a substituent, an N-octadecyl-4-stilbazole cation (N-octadecyl-4-styrylpyridinium cation) unsubstituted or substituted with a substituent, a mono(2-acryloyloxyethyl)succinate anion unsubstituted or substituted with a substituent, and a 3-(acryloyloxy)propane-1-sulfonate anion unsubstituted or substituted with a substituent.

Examples of the organic ion (b) substituted with a substituent include propoxycinnamate anion, bis(4-tert-butylphenyl)iodonium cation, tris(4-tert-butylphenyl)sulfonium cation, and the like.

In terms of further reducing the size of the ionic salt and further improving resolution, the molecular weight of the organic ion (b) may be in a range of about 50 or more to about 5,000 or less, more specifically, in a range of about 100 or more to about 1,000 or less.

<Specific Examples of the Ionic Salt>

Specific examples of the ionic salt are as follows.

[Sn₈W₁₈O₆₆]⁸⁻-8[4-[4-(dimethylamino)styryl]-1-methylpyridinium cation]

[Sn₈W₁₈O₆₆]⁸⁻-8[diphenyliodonium cation]

[Sn₈W₁₈O₆₆]⁸⁻-8[bis(4-tert-butylphenyl)iodonium cation]

[Sn₈W₁₈O₆₆]⁸⁻-8[triphenyl sulfonium cation]

[Sn₈W₁₈O₆₆]⁸⁻-8[tris(4-tert-butylphenyl)sulfonium cation]

[Sn₈W₁₈O₆₆]⁸⁻-8[N-octadecyl-4-stilbazole cation]

[Sn₄W₂Si₂O₆₈]¹⁴⁻-14[4-[4-(dimethylamino)styryl]-1-methylpyridinium cation]

[Sn₄W₂Si₂O₆₈]¹⁴⁻-14[diphenyliodonium cation]

[Sn₄W₂Si₂O₆₈]¹⁴⁻-14[bis(4-tert-butylphenyl)iodonium cation]

[Sn₄W₂Si₂O₆₈]¹⁴⁻-14[triphenyl sulfonium cation]

[Sn₄W₂Si₂O₆₈]¹⁴⁻-14[tris(4-tert-butylphenyl)sulfonium cation]

[Sn₄W₂Si₂O₆₈]¹⁴⁻-14[N-octadecyl-4-stilbazole cation]

[Sn₃W₁₈Si₂O₆₈]¹⁴⁻-14[4-[4-(dimethylamino)styryl]-1-methylpyridinium cation]

[Sn₃W₁₈Si₂O₆₈]¹⁴⁻-14[diphenyliodonium cation]

[Sn₃W₁₈Si₂O₆₈]¹⁴⁻-14[bis(4-tert-butylphenyl)iodonium cation]

[Sn₃W₁₈Si₂O₆₈]¹⁴⁻-14[triphenyl sulfonium cation]

[Sn₃W₁₈Si₂O₆₈]¹⁴⁻-14[tris(4-tert-butylphenyl)sulfonium cation]

[Sn₃W₁₈Si₂O₆₈]¹⁴-14[N-octadecyl-4-stilbazole cation]

[Sn₃W₁₈P₂O₆₈]¹²⁻-12[4-[4-(dimethylamino)styryl]-1-methylpyridinium cation]

[Sn₃W₁₈P₂O₆₈]¹²⁻-12[diphenyliodonium cation]

[Sn₃W₁₈P₂O₆₈]¹²⁻-12[bis(4-tert-butylphenyl)iodonium cation]

[Sn₃W₁₈P₂O₆₈]¹²⁻-12[triphenyl sulfonium cation]

[Sn₃W₁₈P₂O₆₈]¹²⁻-12[tris(4-tert-butylphenyl)sulfonium cation]

[Sn₃W₁₈P₂O₆₈]¹²⁻-12[N-octadecyl-4-stilbazole cation]

[SnW₁₂H₂O₄₂]⁸⁻-8[4-[4-(dimethylamino)styryl]-1-methylpyridinium cation]

[SnW₁₂H₂O₄₂]⁸⁻-8[diphenyliodonium cation]

[SnW₁₂H₂O₄₂]⁸⁻-8[bis(4-tert-butylphenyl)iodonium cation]

[SnW₁₂H₂O₄₂]⁸⁻-8[triphenyl sulfonium cation]

[SnW₁₂H₂O₄₂]⁸⁻-8[tris(4-tert-butylphenyl)sulfonium cation]

[SnW₁₂H₂O₄₂]⁸⁻-8[N-octadecyl-4-stilbazole cation]

[W₂₈Te₁₀O₁₁₈]²⁸⁻-28[4-[4-(dimethylamino)styryl]-1-methylpyridinium cation]

[W₂₈Te₁₀O₁₁₈]²⁸⁻-28[diphenyliodonium cation]

[W₂₈Te₁₀O₁₁₈]²⁸⁻-28[bis(4-tert-butylphenyl)iodonium cation]

[W₂₈Te₁₀O₁₁₈]²⁸⁻-28[triphenyl sulfonium cation]

[W₂₈Te₁₀O₁₁₈]²⁸⁻-28[tris(4-tert-butylphenyl)sulfonium cation]

[W₂₈Te₁₀O₁₀₈]²⁸⁻-28[N-octadecyl-4-stilbazole cation]

[W₁₈Te₂Cu₃H₆O₆₉]¹⁰⁻-10[4-[4-(dimethylamino)styryl]-1-methylpyridinium cation]

[W₁₈Te₂Cu₃H₆O₆₉]¹⁰-10[diphenyliodonium cation]

[W₁₈Te₂Cu₃H₆O₆₉]¹⁰⁻-10[bis(4-tert-butylphenyl)iodonium cation]

[W₁₈Te₂Cu₃H₆O₆₉]¹⁰⁻-10[triphenyl sulfonium cation]

[W₁₈Te₂Cu₃H₆O₆₉]¹⁰-10[tris(4-tert-butylphenyl)sulfonium cation]

[W₁₈Te₂Cu₃H₆O₆₉]¹⁰⁻-10[N-octadecyl-4-stilbazole cation]

[W₂₀Te₄H₂O₈₀]²²⁻-22[4-[4-(dimethylamino)styryl]-1-methylpyridinium cation]

[W₂₀Te₄H₂O₈₀]²²⁻-22[diphenyliodonium cation]

[W₂₀Te₄H₂O₈₀]²²⁻-22[bis(4-tert-butylphenyl)iodonium cation]

[W₂₀Te₄H₂O₈₀]²²⁻-22[triphenyl sulfonium cation]

[W₂₀Te₄H₂O₈₀]²²⁻-22[tris(4-tert-butylphenyl)sulfonium cation]

[W₂₀Te₄H₂O₈₀]²²⁻-22[N-octadecyl-4-stilbazole cation]

[W₂₈Te₉O₁₁₂]²⁴⁻-24[4-[4-(dimethylamino)styryl]-1-methylpyridinium cation]

[W₂₈Te₉O₁₁₂]²⁴⁻-24[diphenyliodonium cation]

[W₂₈Te₉O₁₁₂]²⁴⁻-24[bis(4-tert-butylphenyl)iodonium cation]

[W₂₈Te₉O₁₁₂]²⁴−0.24[triphenyl sulfonium cation]

[W₂₈Te₉O₁₁₂]²⁴−0.24[tris(4-tert-butylphenyl)sulfonium cation]

[W₂₈Te₉O₁₁₂]²⁴⁻-24[N-octadecyl-4-stilbazole cation]

[W₅₈Te₂H₁₀O₁₉₈]²⁶⁻-26[4-[4-(dimethylamino)styryl]-1-methylpyridinium cation]

[W₅₈Te₂H₁₀O₁₉₈]²⁶⁻-26[diphenyliodonium cation]

[W₅₈Te₂H₁₀O₁₉₈]²⁶⁻-26[bis(4-tert-butylphenyl)iodonium cation]

[W₅₈Te₂H₁₀O₁₉₈]²⁶⁻-26[triphenyl sulfonium cation]

[W₅₈Te₂H₁₀O₁₉₈]²⁶⁻-26[tris(4-tert-butylphenyl)sulfonium cation]

[W₅₈Te₂H₁₀O₁₉₈]²⁶⁻-26[N-octadecyl-4-stilbazole cation]

[W₁₈TeH₃O₆₃]⁵⁻-5[4-[4-(dimethylamino)styryl]-1-methylpyridinium cation]

[W₁₈TeH₃O₆₃]⁵⁻-5[diphenyliodonium cation]

[W₁₈TeH₃O₆₃]⁵⁻-5[bis(4-tert-butylphenyl)iodonium cation]

[W₁₈TeH₃O₆₃]⁵⁻-5[triphenyl sulfonium cation]

[W₁₈TeH₃O₆₃]⁵⁻-5[tris(4-tert-butylphenyl)sulfonium cation]

[W₁₈TeH₃O₆₃]⁵⁻-5[N-octadecyl-4-stilbazole cation]

[W₁₈TeH₃O₆₂]⁷⁻-7[4-[4-(dimethylamino)styryl]-1-methylpyridinium cation]

[W₁₈TeH₃O₆₂]⁷⁻-7[diphenyliodonium cation]

[W₁₈TeH₃O₆₂]⁷⁻-7[bis(4-tert-butylphenyl)iodonium cation]

[W₁₈TeH₃O₆₂]⁷⁻-7[triphenyl sulfonium cation]

[W₁₈TeH₃O₆₂]⁷⁻-7[tris(4-tert-butylphenyl)sulfonium cation]

[W₁₈TeH₃O₆₂]⁷⁻-7[N-octadecyl-4-stilbazole cation]

[W₆TeO₂₄]⁶⁻-6[4-[4-(dimethylamino)styryl]-1-methylpyridinium cation]

[W₆TeO₂₄]⁶⁻-6[diphenyliodonium cation]

[W₆TeO₂₄]⁶⁻-6[bis(4-tert-butylphenyl)iodonium cation]

[W₆TeO₂₄]⁶⁻-6[triphenyl sulfonium cation]

[W₆TeO₂₄]⁶⁻-6[tris(4-tert-butylphenyl)sulfonium cation]

[W₆TeO₂₄]⁶⁻-6[N-octadecyl-4-stilbazole cation]

[W₁₇Te₂O₆₁]¹²⁻-12[4-[4-(dimethylamino)styryl]-1-methylpyridinium cation]

[W₁₇Te₂O₆₁]¹²⁻-12[diphenyliodonium cation]

[W₁₇Te₂O₆₁]¹²⁻-12[bis(4-tert-butylphenyl)iodonium cation]

[W₁₇Te₂O₆₁]¹²⁻-12[triphenyl sulfonium cation]

[W₁₇Te₂O₆₁]¹²⁻-12[tris(4-tert-butylphenyl)sulfonium cation]

[W₁₇Te₂O₆₁]¹²⁻-12[N-octadecyl-4-stilbazole cation]

[W₁₅TeNaO₅₄]¹³⁻-13[4-[4-(dimethylamino)styryl]-1-methylpyridinium cation]

[W₁₅TeNaO₅₄]¹³⁻-13[diphenyliodonium cation]

[W₁₅TeNaO₅₄]¹³⁻-13[bis(4-tert-butylphenyl)iodonium cation]

[W₁₅TeNaO₅₄]¹³⁻-13[triphenyl sulfonium cation]

[W₁₅TeNaO₅₄]¹³⁻-13[tris(4-tert-butylphenyl)sulfonium cation]

[W₁₅TeNaO₅₄]¹³⁻-13[N-octadecyl-4-stilbazole cation]

[Te₄C₈H₂₀]²⁺-2[4-azidobenzoate anion]

[Te₄C₈H₂₀]²⁺-2[cinnamate anion]

[Te₄C₈H₂₀]²⁺-2[4-propoxy cinnamate anion]

[Te₄C₈H₂₀]²⁺-2[nicotinate anion]

[Te₄C₈H₂₀]²⁺-2[ketoprofen anion]

[Te₄C₈H₂₀]²⁺-2[6-maleimide caproate anion]

[Te₄C₈H₂₀]²⁺-2[4-naphthoquinone diazide sulfonate anion]

[Te₄C₈H₂₀]²⁺-2[5-naphthoquinone diazide sulfonate anion]

[Te₄C₈H₂₀]²⁺-2[6-naphthoquinone diazide sulfonate anion]

[Te₄C₈H₂₀]²⁺-2[anthraquinone-1-sulfonate anion]

[Te₄C₈H₂₀]²⁺-2[anthraquinone-2-sulfonate anion]

[Te₄C₈H₂₀]²⁺-2[9,10-dimethoxyanthracene-2-sulfonate anion]

[Te₄C₈H₂₀]²⁺-2[mono(2-acryloyloxyethyl)succinate anion]

[Te₄C₈H₂₀]²⁺-2[3-(acryloyloxy)propane-1-sulfonate anion]

[InW₁₁PH₄O₄₀]⁴⁻-4[4-[4-(dimethylamino)styryl]-1-methylpyridinium cation]

[InW₁₁PH₄O₄₀]⁴⁻-4[diphenyliodonium cation]

[InW₁₁PH₄O₄₀]⁴⁻-4[bis(4-tert-butylphenyl)iodonium cation]

[InW₁₁PH₄O₄₀]⁴⁻-4[triphenyl sulfonium cation]

[InW₁₁PH₄O₄₀]⁴⁻-4[tris(4-tert-butylphenyl)sulfonium cation]

[InW₁₁PH₄O₄₀]⁴⁻-4[N-octadecyl-4-stilbazole cation]

[InW₁₁SiH₄O₄₀]⁵⁻-5[4-[4-(dimethylamino)styryl]-1-methylpyridinium cation]

[InW₁₁SiH₄O₄₀]⁵⁻-5[diphenyliodonium cation]

[InW₁₁SiH₄O₄₀]⁵⁻-5[bis(4-tert-butylphenyl)iodonium cation]

[InW₁₁SiH₄O₄₀]⁵⁻-5[triphenyl sulfonium cation]

[InW₁₁SiH₄O₄₀]⁵⁻-5[tris(4-tert-butylphenyl)sulfonium cation]

[InW₁₁SiH₄O₄₀]⁵⁻-5[N-octadecyl-4-stilbazole cation]

[InW₃O₄(C₂H₄COO)₈]²²⁻-22[4-[4-(dimethylamino)styryl]-1-methylpyridinium cation]

[InW₃O₄(C₂H₄COO)₈]²²⁻-22[diphenyliodonium cation]

[InW₃O₄(C₂H₄COO)₈]²²⁻-22[bis(4-tert-butylphenyl)iodonium cation]

[InW₃O₄(C₂H₄COO)₈]²²⁻-22[triphenyl sulfonium cation]

[InW₃O₄(C₂H₄COO)₈]²²⁻-22[tris(4-tert-butylphenyl)sulfonium cation]

[InW₃O₄(C₂H₄COO)₈]²²⁻-22[N-octadecyl-4-stilbazole cation]

[Sb₂I₉]⁻-[4-[4-(dimethylamino)styryl]-1-methylpyridinium cation]

[Sb₂I₉]⁻-[diphenyliodonium cation]

[Sb₂I₉]⁻-[bis(4-tert-butylphenyl)iodonium cation]

[Sb₂I₉]⁻-[triphenyl sulfonium cation]

[Sb₂I₉]⁻-[tris(4-tert-butylphenyl)sulfonium cation]

[Sb₂I₉]⁻—[N-octadecyl-4-stilbazole cation]

[{(4-chlorophenyl)Sb}12Na₂H₉O₃₀]⁻-[4-[4-(dimethylamino)styryl]-1-methylpyridinium cation]

[{(4-chlorophenyl)Sb}₁₂Na₂H₉O₃₀]⁻-[diphenyliodonium cation]

[{(4-chlorophenyl)Sb}₁₂Na₂H₉O₃₀]⁻-[bis(4-tert-butylphenyl)iodonium cation]

[{(4-chlorophenyl)Sb}₁₂Na₂H₉O₃₀]⁻-[triphenyl sulfonium cation]

[{(4-chlorophenyl)Sb}₁₂Na₂H₉O₃₀]⁻-[tris(4-tert-butylphenyl)sulfonium cation]

[{(4-chlorophenyl)Sb}₁₂Na₂H₉O₃₀]⁻—[N-octadecyl-4-stilbazole cation]

[(SbW₉O₃₃)₂{Nb(C₂H₄)}₂]¹²⁻-12[4-[4-(dimethylamino)styryl]-1-methylpyridinium cation]

[(SbW₉O₃₃)₂{Nb(C₂H₄)}₂]¹²⁻-12[diphenyliodonium cation]

[(SbW₉O₃₃)₂{Nb(C₂H₄)}₂]¹²⁻-12[bis(4-tert-butylphenyl)iodonium cation]

[(SbW₉O₃₃)₂{Nb(C₂H₄)}₂]¹²⁻-12[triphenyl sulfonium cation]

[(SbW₉O₃₃)₂{Nb(C₂H₄)}₂]¹²⁻-12[tris(4-tert-butylphenyl)sulfonium cation]

[(SbW₉O₃₃)₂{Nb(C₂H₄)}₂]¹²⁻-12[N-octadecyl-4-stilbazole cation]

[Mo₂Te₁₂]⁶⁺-6[4-azidobenzoate anion]

[Mo₂Te₁₂]⁶⁺-6[cinnamate anion]

[Mo₂Te₁₂]⁶⁺-6[4-propoxy cinnamate anion]

[Mo₂Te₁₂]⁶⁺-6[nicotinate anion]

[Mo₂Te₁₂]⁶⁺-6[ketoprofen anion]

[Mo₂Te₁₂]⁶⁺-6[6-maleimide caproate anion]

[Mo₂Te₁₂]⁶⁺-6[4-naphthoquinone diazide sulfonate anion]

[Mo₂Te₁₂]⁶⁺-6[5-naphthoquinone diazide sulfonate anion]

[Mo₂Te₁₂]⁶⁺-6[6-naphthoquinone diazide sulfonate anion]

[Mo₂Te₁₂]⁶⁺-6[anthraquinone-1-sulfonate anion]

[Mo₂Te₁₂]⁶⁺-6[anthraquinone-2-sulfonate anion]

[Mo₂Te₁₂]⁶⁺-6[9,10-dimethoxyanthracene-2-sulfonate anion]

[Mo₂Te₁₂]⁶⁺-6[mono(2-acryloyloxyethyl)succinate anion]

[Mo₂Te₁₂]⁶⁺-6[3-(acryloyloxy)propane-1-sulfonate anion]

[NbTe₁₀]³⁻-3[4-[4-(dimethylamino)styryl]-1-methylpyridinium cation]

[NbTe₁₀]³⁻-3[diphenyliodonium cation]

[NbTe₁₀]³⁻-3[bis(4-tert-butylphenyl)iodonium cation]

[NbTe₁₀]³⁻-3[triphenyl sulfonium cation]

[NbTe₁₀]³⁻-3[tris(4-tert-butylphenyl)sulfonium cation]

[NbTe₁₀]³⁻-3[N-octadecyl-4-stilbazole cation]

[Ru₆(Te₂)₇(CO)₁₂]²⁻-2[4-[4-(dimethylamino)styryl]-1-methylpyridinium cation]

[Ru₆(Te₂)₇(CO)₁₂]²⁻-2[diphenyliodonium cation]

[Ru₆(Te₂)₇(CO)₁₂]²⁻-2[bis(4-tert-butylphenyl)iodonium cation]

[Ru₆(Te₂)₇(CO)₁₂]²⁻-2[triphenyl sulfonium cation]

[Ru₆(Te₂)₇(CO)₁₂]²⁻-2[tris(4-tert-butylphenyl)sulfonium cation]

[Ru₆(Te₂)₇(CO)₁₂]²⁻-2[N-octadecyl-4-stilbazole cation]

[(SbW₉O₃₃)₂{Nb(C₂H₄)}₂]¹²⁻-12[4-[4-(dimethylamino)styryl]-1-methylpyridinium cation]

[(SbW₉O₃₃)₂{Nb(C₂H₄)}₂]¹²⁻-12[diphenyliodonium cation]

[(SbW₉O₃₃)₂{Nb(C₂H₄)}₂]¹²⁻-12[bis(4-tert-butylphenyl)iodonium cation]

[(SbW₉O₃₃)₂{Nb(C₂H₄)}₂]¹²⁻-12[triphenyl sulfonium cation]

[(SbW₉O₃₃)₂{Nb(C₂H₄)}₂]¹²⁻-12[tris(4-tert-butylphenyl)sulfonium cation]

[(SbW₉O₃₃)₂{Nb(C₂H₄)}₂]¹²⁻-12[N-octadecyl-4-stilbazole cation]

[MoTe₈O]²⁺-2[4-azidobenzoate anion]

[MoTe₈O]²⁺-2[cinnamate anion]

[MoTe₈O]²⁺-2[4-propoxy cinnamate anion]

[MoTe₈O]²⁺-2[nicotinate anion]

[MoTe₈O]²⁺-2[ketoprofen anion]

[MoTe₈O]²⁺-2[6-maleimide caproate anion]

[MoTe₈O]²⁺-2[4-naphthoquinone diazide sulfonate anion]

[MoTe₈O]²⁺-2[5-naphthoquinone diazide sulfonate anion]

[MoTe₈O]²⁺-2[6-naphthoquinone diazide sulfonate anion]

[MoTe₈O]²⁺-2[anthraquinone-1-sulfonate anion]

[MoTe₈O]²⁺-2[anthraquinone-2-sulfonate anion]

[MoTe₈O]²⁺-2[9,10-dimethoxyanthracene-2-sulfonate anion]

[MoTe₈O]²⁺-2[mono(2-acryloyloxyethyl)succinate anion]

[MoTe₈O]²⁺-2[3-(acryloyloxy)propane-1-sulfonate anion]

[Bi₆(CH₃OH)₂(NO₃)₃(OH₂)₂(Sha_{-1H})₁₂]²⁺-2[4-azidobenzoate anion]

[Bi₆(CH₃OH)₂(NO₃)₃(OH₂)₂(Sha_{-1H})₁₂]²⁺-2[cinnamate anion]

[Bi₆(CH₃OH)₂(NO₃)₃(OH₂)₂(Sha_{-1H})₁₂]²⁺-2[4-propoxy cinnamate anion]

[Bi₆(CH₃OH)₂(NO₃)₃(OH₂)₂(Sha_{-1H})₁₂]²⁺-2[nicotinate anion]

[Bi₆(CH₃OH)₂(NO₃)₃(OH₂)₂(Sha_{-1H})₁₂]²⁺-2[ketoprofen anion]

[Bi₆(CH₃OH)₂(NO₃)₃(OH₂)₂(Sha_{-1H})₁₂]²⁺-2[6-maleimide caproate anion]

[Bi₆(CH₃OH)₂(NO₃)₃(OH₂)₂(Sha_{-1H})₁₂]²⁺-2[4-naphthoquinone diazide sulfonate anion]

[Bi₆(CH₃OH)₂(NO₃)₃(OH₂)₂(Sha_{-1H})₁₂]²⁺-2[5-naphthoquinone diazide sulfonate anion]

[Bi₆(CH₃OH)₂(NO₃)₃(OH₂)₂(Sha_{-1H})₁₂]²⁺-2[6-naphthoquinone diazide sulfonate anion]

[Bi₆(CH₃OH)₂(NO₃)₃(OH₂)₂(Sha_{-1H})₁₂]²⁺-2[anthraquinone-1-sulfonate anion]

[Bi₆(CH₃OH)₂(NO₃)₃(OH₂)₂(Sha_{-1H})₁₂]²⁺-2[anthraquinone-2-sulfonate anion]

[Bi₆(CH₃OH)₂(NO₃)₃(OH₂)₂(Sha_{-1H})₁₂]²⁺-2[9,10-dimethoxyanthracene-2-sulfonate anion]

[Bi₆(CH₃OH)₂(NO₃)₃(OH₂)₂(Sha_{-1H})₁₂]²⁺-2[mono(2-acryloyloxyethyl)succinate anion]

[Bi₆(CH₃OH)₂(NO₃)₃(OH₂)₂(Sha_{-1H})₁₂]²⁺-2[3-(acryloyloxy)propane-1-sulfonate anion]

[Bi₆O₄(OH)₄(H₂₀)₆]²⁺-2[4-azidobenzoate anion]

[Bi₆O₄(OH)₄(H₂₀)₆]²⁺-2[cinnamate anion]

[Bi₆O₄(OH)₄(H₂₀)₆]²⁺-2[4-propoxy cinnamate anion]

[Bi₆O₄(OH)₄(H₂₀)₆]²⁺-2[nicotinate anion]

[Bi₆O₄(OH)₄(H₂₀)₆]²⁺-2[ketoprofen anion]

[Bi₆O₄(OH)₄(H₂₀)₆]²⁺-2[6-maleimide caproate anion]

[Bi₆O₄(OH)₄(H₂O)₆]²⁺-2[4-naphthoquinone diazide sulfonate anion]

[Bi₆O₄(OH)₄(H₂O)₆]²⁺-2[5-naphthoquinone diazide sulfonate anion]

[Bi₆O₄(OH)₄(H₂O)₆]²⁺-2[6-naphthoquinone diazide sulfonate anion]

[Bi₆O₄(OH)₄(H₂₀)₆]²⁺-2[anthraquinone-1-sulfonate anion]

[Bi₆O₄(OH)₄(H₂₀)₆]²⁺-2[anthraquinone-2-sulfonate anion]

[Bi₆O₄(OH)₄(H₂₀)₆]²⁺-2[9,10-dimethoxyanthracene-2-sulfonate anion]

[Bi₆O₄(OH)₄(H₂₀)₆]²⁺-2[mono(2-acryloyloxyethyl)succinate anion]

[Bi₆O₄(OH)₄(H₂O)₆]²⁺-2[3-(acryloyloxy)propane-1-sulfonate anion]

[Bi₆O₄(OH)₄(NO₃)₅(H₂O)]⁺-[4-azidobenzoate anion]

[Bi₆O₄(OH)₄(NO₃)₅(H₂O)]⁺-[cinnamate anion]

[Bi₆O₄(OH)₄(NO₃)₅(H₂O)]⁺-[4-propoxy cinnamate anion]

[Bi₆O₄(OH)₄(NO₃)₅(H₂O)]⁺-[nicotinate anion]

[Bi₆O₄(OH)₄(NO₃)₅(H₂O)]⁺-[ketoprofen anion]

[Bi₆O₄(OH)₄(NO₃)₅(H₂O)]⁺-[6-maleimide caproate anion]

[Bi₆O₄(OH)₄(NO₃)₅(H₂O)]⁺-[4-naphthoquinone diazide sulfonate anion]

[Bi₆O₄(OH)₄(NO₃)₅(H₂O)]⁺-[5-naphthoquinone diazide sulfonate anion]

[Bi₆O₄(OH)₄(NO₃)₅(H₂O)]⁺-[6-naphthoquinone diazide sulfonate anion]

[Bi₆O₄(OH)₄(NO₃)₅(H₂O)]⁺-[anthraquinone-1-sulfonate anion]

[Bi₆O₄(OH)₄(NO₃)₅(H₂O)]⁺-[anthraquinone-2-sulfonate anion]

[Bi₆O₄(OH)₄(NO₃)₅(H₂O)]⁺-[9,10-dimethoxyanthracene-2-sulfonate anion]

[Bi₆O₄(OH)₄(NO₃)₅(H₂O)]⁺-[mono(2-acryloyloxyethyl)succinate anion]

[Bi₆O₄(OH)₄(NO₃)₅(H₂O)]⁺-[3-(acryloyloxy)propane-1-sulfonate anion]

[Bi₆O₄OH(cit)₃(H₂O)₃]³⁻-3[4-[4-(dimethylamino)styryl]-1-methylpyridinium cation]

[Bi₆O₄OH(cit)₃(H₂O)₃]³⁻-3[diphenyliodonium cation]

[Bi₆O₄OH(cit)₃(H₂O)₃]³⁻-3[bis(4-tert-butylphenyl)iodonium cation]

[Bi₆O₄OH(cit)₃(H₂O)₃]³⁻-3[triphenyl sulfonium cation]

[Bi₆O₄OH(cit)₃(H₂O)₃]³⁻-3[tris(4-tert-butylphenyl)sulfonium cation]

[Bi₆O₄OH(cit)₃(H₂O)₃]³⁻-3[N-octadecyl-4-stilbazole cation]

[Pr₄Sb₁₂O₁₈Cl₁₇]⁵⁻-5[4-[4-(dimethylamino)styryl]-1-methylpyridinium cation]

[Pr₄Sb₁₂O₁₈Cl₁₇]⁵⁻-5[diphenyliodonium cation]

[Pr₄Sb₁₂O₁₈Cl₁₇]⁵⁻-5[bis(4-tert-butylphenyl)iodonium cation]

[Pr₄Sb₁₂O₁₈Cl₁₇]⁵⁻-5[triphenyl sulfonium cation]

[Pr₄Sb₁₂O₁₈Cl₁₇]⁵⁻-5[tris(4-tert-butylphenyl)sulfonium cation]

[Pr₄Sb₁₂O₁₈Cl₁₇]⁵⁻-5[N-octadecyl-4-stilbazole cation]

[Pr₄Sb₁₂O₁₈Cl₁₄(1,3-bdc)]⁴⁻-4[4-[4-(dimethylamino)styryl]-1-methylpyridinium cation]

[Pr₄Sb₁₂O₁₈Cl₁₄(1,3-bdc)]⁴⁻-4[diphenyliodonium cation]

[Pr₄Sb₁₂O₁₈Cl₁₄(1,3-bdc)]⁴⁻-4[bis(4-tert-butylphenyl)iodonium cation]

[Pr₄Sb₁₂O₁₈Cl₁₄(1,3-bdc)]⁴⁻-4[triphenyl sulfonium cation]

[Pr₄Sb₁₂O₁₈Cl₁₄(1,3-bdc)]⁴⁻-4[tris(4-tert-butylphenyl)sulfonium cation]

[Pr₄Sb₁₂O₁₈Cl₁₄(1,3-bdc)]⁴⁻-4[N-octadecyl-4-stilbazole cation]

[Pr₄Sb₁₂O₁₈Cl₁₁(1,4-bdc)₂]³⁻-3[4-[4-(dimethylamino)styryl]-1-methylpyridinium cation]

[Pr₄Sb₁₂O₁₈Cl₁₁(1,4-bdc)₂]³⁻-3[diphenyliodonium cation]

[Pr₄Sb₁₂O₁₈Cl₁₁(1,4-bdc)₂]³⁻-3[bis(4-tert-butylphenyl)iodonium cation]

[Pr₄Sb₁₂O₁₈Cl₁₁(1,4-bdc)₂]³⁻-3[triphenyl sulfonium cation]

[Pr₄Sb₁₂O₁₈Cl₁₁(1,4-bdc)₂]³⁻-3[tris(4-tert-butylphenyl)sulfonium cation]

[Pr₄Sb₁₂O₁₈Cl₁₁(1,4-bdc)₂]³⁻-3[N-octadecyl-4-stilbazole cation]

[OIn₆(taci_{-3H})₄]⁴⁺-4[4-azidobenzoate anion]

[OIn₆(taci_{-3H})₄]⁴⁺-4[cinnamate anion]

[OIn₆(taci_{-3H})₄]⁴⁺-4[4-propoxy cinnamate anion]

[OIn₆(taci_{-3H})₄]⁴⁺-4[nicotinate anion]

[OIn₆(taci_{-3H})₄]⁴⁺-4[ketoprofen anion]

[OIn₆(taci_{-3H})₄]⁴⁺-[6-maleimide caproate anion]

[OIn₆(taci_{-3H})₄]⁴⁺-4[4-naphthoquinone diazide sulfonate anion]

[OIn₆(taci_{-3H})₄]⁴⁺-4[5-naphthoquinone diazide sulfonate anion]

[OIn₆(taci_{-3H})₄]⁴⁺-4[6-naphthoquinone diazide sulfonate anion]

[OIn₆(taci_{-3H})₄]⁴⁺-4[anthraquinone-1-sulfonate anion]

[OIn₆(taci_{-3H})₄]⁴⁺-4[anthraquinone-2-sulfonate anion]

[OIn₆(taci_{-3H})₄]⁴⁺-4[9,10-dimethoxyanthracene-2-sulfonate anion]

[OIn₆(taci_{-3H})₄]⁴⁺-4[mono(2-acryloyloxyethyl)succinate anion]

[OIn₆(taci_{-3H})₄]⁴⁺-4[3-(acryloyloxy)propane-1-sulfonate anion]

[In₃Te₇]⁵⁻-5[4-[4-(dimethylamino)styryl]-1-methylpyridinium cation]

[In₃Te₇]⁵⁻-5[diphenyliodonium cation]

[In₃Te₇]⁵⁻-5[bis(4-tert-butylphenyl)iodonium cation]

[In₃Te₇]⁵⁻-5[triphenyl sulfonium cation]

[In₃Te₇]⁵⁻-5[tris(4-tert-butylphenyl)sulfonium cation]

[In₃Te₇]⁵⁻-5[N-octadecyl-4-stilbazole cation]

{[Bi₆O₅(OH)₃(NO₃)₃]₂}⁴⁺-4[4-azidobenzoate anion]

{[Bi₆O₅(OH)₃(NO₃)₃]₂}⁴⁺-4[cinnamate anion]

{[Bi₆O₅(OH)₃(NO₃)₃]₂}⁴⁺-4[4-propoxy cinnamate anion]

{[Bi₆O₅(OH)₃(NO₃)₃]₂}⁴⁺-4[nicotinate anion]

{[Bi₆O₅(OH)₃(NO₃)₃]₂}⁴⁺-4[ketoprofen anion]

{[Bi₆O₅(OH)₃(NO₃)₃]₂}⁴⁺-4[6-maleimide caproate anion]

{[Bi₆O₅(OH)₃(NO₃)₃]₂}⁴⁺-4[4-naphthoquinone diazide sulfonate anion]

{[Bi₆O₅(OH)₃(NO₃)₃]₂}⁴⁺-4[5-naphthoquinone diazide sulfonate anion]

{[Bi₆O₅(OH)₃(NO₃)₃]₂}⁴⁺-4[6-naphthoquinone diazide sulfonate anion]

{[Bi₆O₅(OH)₃(NO₃)₃]₂}⁴⁺-4[anthraquinone-1-sulfonate anion]

{[Bi₆O₅(OH)₃(NO₃)₃]₂}⁴⁺-4[anthraquinone-2-sulfonate anion]

{[Bi₆O₅(OH)₃(NO₃)₃]₂}⁴⁺-4[9,10-dimethoxyanthracene-2-sulfonate anion]

{[Bi₆O₅(OH)₃(NO₃)₃]₂}⁴⁺-4[mono(2-acryloyloxyethyl)succinate anion]

{[Bi₆O₅(OH)₃(NO₃)₃]₂}⁴⁺-4[3-(acryloyloxy)propane-1-sulfonate anion]

[Bi₉O₈(OH)₆]⁵⁺-5[4-azidobenzoate anion]

[Bi₉O₈(OH)₆]⁵⁺-5[cinnamate anion]

[Bi₉O₈(OH)₆]⁵⁺-5[4-propoxy cinnamate anion]

[Bi₉O₈(OH)₆]⁵⁺-5[nicotinate anion]

[Bi₉O₈(OH)₆]⁵⁺-5[ketoprofen anion]

[Bi₉O₈(OH)₆]⁵⁺-5[6-maleimide caproate anion]

[Bi₉O₈(OH)₆]⁵⁺-5[4-naphthoquinone diazide sulfonate anion]

[Bi₉O₈(OH)₆]⁵⁺-5[5-naphthoquinone diazide sulfonate anion]

[Bi₉O₈(OH)₆]⁵⁺-5[6-naphthoquinone diazide sulfonate anion]

[Bi₉O₈(OH)₆]⁵⁺-5[anthraquinone-1-sulfonate anion]

[Bi₉O₈(OH)₆]⁵⁺-5[anthraquinone-2-sulfonate anion]

[Bi₉O₈(OH)₆]⁵⁺-5[9,10-dimethoxyanthracene-2-sulfonate anion]

[Bi₉O₈(OH)₆]⁵⁺-5[mono(2-acryloyloxyethyl)succinate anion]

[Bi₉O₈(OH)₆]⁵⁺-5[3-(acryloyloxy)propane-1-sulfonate anion]

[Bi₉O₈(OC₂H₄)₆]⁵⁺-5[4-azidobenzoate anion]

[Bi₉O₈(OC₂H₄)₆]⁵⁺-5[cinnamate anion]

[Bi₉O₈(OC₂H₄)₆]⁵⁺-5[4-propoxy cinnamate anion]

[Bi₉O₈(OC₂H₄)₆]⁵⁺-5[nicotinate anion]

[Bi₉O₈(OC₂H₄)₆]⁵⁺-5[ketoprofen anion]

[Bi₉O₈(OC₂H₄)₆]⁵⁺-5[6-maleimide caproate anion]

[Bi₉O₈(OC₂H₄)₆]⁵⁺-5[4-naphthoquinone diazide sulfonate anion]

[Bi₉O₈(OC₂H₄)₆]⁵⁺-5[5-naphthoquinone diazide sulfonate anion]

[Bi₉O₈(OC₂H₄)₆]⁵⁺-5[6-naphthoquinone diazide sulfonate anion]

[Bi₉O₈(OC₂H₄)₆]⁵⁺-5[anthraquinone-1-sulfonate anion]

[Bi₉O₈(OC₂H₄)₆]⁵⁺-5[anthraquinone-2-sulfonate anion]

[Bi₉O₈(OC₂H₄)₆]⁵⁺-5[9,10-dimethoxyanthracene-2-sulfonate anion]

[Bi₉O₈(OC₂H₄)₆]⁵⁺-5[mono(2-acryloyloxyethyl)succinate anion]

[Bi₉O₈(OC₂H₄)₆]⁵⁺-5[3-(acryloyloxy)propane-1-sulfonate anion]

The structure (composition) of the ionic salt may be identified by performing FT-IR analysis, NMR analysis, fluorescence X-ray (XRF) analysis, mass analysis, UV analysis, single crystal X-ray structure analysis, power X-ray diffraction (PXRD) analysis, liquid chromatography (LC) analysis, size exclusion chromatography (SEC) analysis, thermal analysis, and the like. The specific method of identification used is as described in Examples.

In the interest of improving resolution, the total molecular weight of the ionic salt may be in a range of about 650 or more to about 30,000 or less, and more specifically, in a range of about 900 or more to about 15,000 or less.

Further, in terms of radiation absorption and photosensitivity, the ratio of the molecular weight of the polyvalent ion (a) to the total molecular weight of the organic ion (b) [Molecular weight of (a)/Molecular weight of (b)] in the ionic salt may be in a range of about 0.3 or more to about 30 or less, and more specifically, in a range of about 0.5 or more to about 10 or less.

In particular, the total molecular weight of organic ion (b) refers to the sum of molecular weights of all organic ions (b) included in the ionic salt. For example, where one pentavalent inorganic ion (a) may have 5 monovalent organic ions (b) binding thereto, the sum of molecular weights of these 5 organic ions (b) is referred to as the total molecular weight.

In some example embodiments, in the ionic salt, the polyvalent ion (a) may be cationic and the organic ion (b) may be anionic.

[Preparation Method for Ionic Salt]

The method of preparing the ionic salt is not particularly limited and may include, for example, a method that involves the mixing of a compound having a polyvalent ion (a) including a metal cluster or a metal oxide cluster, with a compound having an organic ion (b), and performing a salt metathesis reaction. The salt metathesis reaction may be carried out by one or more various methods, and if necessary or desirable, purification may be carried out by methods such as one or more of filtration, distillation, extraction, washing with water or organic solvents, recrystallization, a treatment with an acid, a treatment with an alkali, and column chromatography. In particular, among these methods, filtration, column chromatography, or recrystallization may be used. In particular, recrystallization may be used. Such approaches for purification may be repeatedly performed so as to control the concentration of impurities in a composition to a desired range.

The compound having the polyvalent ion (a) and the compound having the organic ion (b) each may be a commercially available product or may be a synthesized product. For the synthesis process of these compounds, any appropriate method may be consulted and employed.

[Radiation-Sensitive Resist Composition]

According to various example embodiments, a radiation-sensitive resist composition including the above-described ionic salt and an organic solvent is provided. The radiation-sensitive resist composition including the ionic salt may have improved radiation (EUV in particular) absorption properties and may have characteristics including improved sensitivity, improved development properties, and/or improved resolution, and the like.

The sensitive resist composition according to various embodiments changes its solubility in developer due to exposure by radiation. The sensitive resist composition according to some example embodiments may be a positive type resist composition which forms a positive-type resist pattern through dissolution and removal of exposed areas of the resist film, or may be a negative-type resist composition which forms a negative-type resist pattern through dissolution and removal of unexposed areas of the resist film. Also, the sensitive resist composition according to some example embodiments may be for an alkaline development process using alkaline developers during a development process of resist pattern formation, or may be for a solvent-based development process using developers containing organic solvents (hereinafter, referred to as organic developer).

Since the ionic salt is already described above, only the organic solvent and optional components, which may be added as needed, will be described hereinbelow. In particular, for the ionic salt included in the radiation-sensitive resist composition, a single ionic salt may be used, or a combination of two or more such ionic salts may be used.

<Organic Solvent>

The organic solvent included in the radiation-sensitive resist composition is not particularly limited as long as the solvent is capable of dissolving at least the ionic salt and optional components, etc., added as necessary or desirable. For the organic solvent, the organic solvent used when synthesizing the ionic salt above, may be used. For the organic solvent, a single organic solvent may be used, or a combination of two or more such organic solvents may be used. Alternatively, a mixed solvent containing a mixture of water and an organic solvent may be used.

Examples of the organic solvent include alcohol-based solvents, ether-based solvents, ketone-based solvents, amide-based solvents, ester-based solvents, sulfoxide-based solvents, hydrocarbon-based solvents, and the like.

More specifically, examples of the alcohol-based solvent include: a monohydric alcohol-based solvent, such as methanol, ethanol, n-propanol, isopropanol, n-butanol, isobutanol, sec-butanol, tert-butanol, n-pentanol, isopentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyhydric alcohol-based solvent, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and a polyhydric alcohol-containing ether-based solvent, such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, and the like.

Examples of the ether-based solvent include: a dialkyl ether-based solvent, such as diethyl ether, dipropyl ether, dibutyl ether, and the like; a cyclic ether-based solvent, such as tetrahydrofuran, tetrahydropyran, and the like; and an aromatic ring-containing ether-based solvent, such as diphenyl ether, anisole, and the like.

Examples of the ketone-based solvent include: a chain ketone-based solvent, such as acetone, methyl ethyl ketone, methyl-n-propyl ketone, methyl-n-butyl ketone, diethyl ketone, methyl isobutyl ketone, 2-heptanone, ethyl-n-butyl ketone, methyl-n-hexyl ketone, diisobutyl ketone, trimethyl nonanone, and the like; a cyclic ketone-based solvent, such as cyclopentanone, cyclohexanone, cycloheptanone, cyclooctanone, methylcyclohexanone, and the like; and 2,4-pentanedione, acetonylacetone, acetophenone, and the like.

Examples of the amide-based solvent include: a cyclic amide-based solvent, such as N,N′-dimethylimidazolidinone, N-methyl-2-pyrrolidone, and the like; and a chain amide-based solvent, such as N-methylformamide, N,N-dimethylformamide, N,N-diethylformamide, acetamide, N-methylacetamide, N,N-dimethylacetamide, N-methylpropionamide, and the like.

Examples of the ester-based solvent include: an acetate ester-based solvent, such as methyl acetate, ethyl acetate, n-propyl acetate, isopropyl acetate, n-butyl acetate, isobutyl acetate, sec-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, and the like; a polyhydric alcohol-containing ether carboxylate-based solvent, such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, and the like; a carbonate-based solvent, such as dimethyl carbonate, diethyl carbonate, ethylene carbonate, propylene carbonate, and the like; a lactate ester-based solvent, such as methyl lactate, ethyl lactate, n-butyl lactate, n-amyl lactate, and the like; and glycol diacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, diethyl phthalate, and the like.

Examples of the sulfoxide-based solvent include dimethyl sulfoxide, diethyl sulfoxide, and the like.

Examples of the hydrocarbon-based solvent include: an aliphatic hydrocarbon-based solvent such as n-pentane, isopentane, n-hexane, isohexane, n-heptane, isoheptane, 2,2,4-trimethyl pentane, n-octane, isooctane, cyclohexane, and methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

In particular, the solvent may be selected from among an alcohol-based solvent, an amide-based solvent, an ester-based solvent, a sulfoxide-based solvent, and any combination thereof. More particularly, the solvent may be selected from among propylene glycol monomethyl ether, propylene glycol monoethyl ether, propylene glycol monomethyl ether acetate, N-methyl-2-pyrrolidone, N,N-dimethylacetamide, ethyl lactate, dimethylsulfoxide, and a combination thereof.

<Optional Components>

In addition to the ionic salt and the organic solvent, the radiation-sensitive resist composition according to some example embodiments may include, as optional components, a radiation sensitive acid generator, a fluorine atom-containing complex, a surfactant, a crosslinking agent, a levelling agent, a coloring agent, or a combination thereof.

The surfactant showed the effect of improving coatability, striations, development properties, and the like. Specific examples of the surfactant include nonionic surfactants, such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, polyethylene glycol distearate, and the like. The surfactant used may be a commercially available product or a synthesized product. Examples of the commercially available product of the surfactant include KP341 (manufactured by Shin-Etsu Chemical Co., Ltd.), Polyflow No. 75 and Polyflow No. 95 (manufactured by Kyoeisha Chemical Co., Ltd.), Ftop EF301, Ftop EF303, and Ftop EF352 (manufactured by Mitsubishi Material Electrochemical Co., Ltd.), MEGAFACE (registered trademark) F171, MEGAFACE F173, R40, R41, and R43 (manufactured by DIC Corp. Ltd.), Fluorad (registered trademark) FC430 and Fluorad FC431 (manufactured by 3M Co., Ltd.), AsahiGuard AG710 (manufactured by AGC Co., Ltd.), Surflon (registered trademark)S-382, Surflon SC-101, Surflon SC-102, Surflon SC-103, Surflon SC-104, Surflon SC-105, and Surflon SC-106 (manufactured by AGC Semi Chemical Co., Ltd.).

Examples of the crosslinking agent include, but are not limited to, a melamine-based crosslinking agent, a substituent element-based crosslinking agent, or a polymer-based crosslinking agent. Examples of the crosslinking agent with at least two crosslinkable substituent groups include methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, and methoxymethylated thiourea.

The levelling agent is for improving the smoothness of coating film when printing (coating) and may be a levelling agent that is commercially available.

In addition, the radiation-sensitive resist composition may utilize a silane coupling agent as an optional component to improve adhesion with a substrate, and the like. Examples of the silane coupling agent include vinyltrimethoxysilane, vinyltriethoxysilane, vinyltrichlorosilane, vinyltris(β-methoxyethoxy)silane; a silane compound containing an unsaturated carbon-carbon bond, such as 3-methacryloxypropyltrimethoxy silane, 3-acryloxypropyltrimethoxy silane, p-styryltrimethoxy silane, 3-methacryloxypropylmethyldimethoxy silane, 3-methacryloxypropylmethyldiethoxy silane, and the like; and trimethoxy[3-(phenyl amino)propyl] silane, and the like.

The amount of such an optional component used may be easily adjustable in accordance with a desired property, and may be appropriately set. For such an optional component, a single optional component may be used, or a combination of two or more such optional components may be used.

There is no particular limitation on the method for forming the radiation-sensitive resist composition, and for example, a method that involves the mixing of an ionic salt and optional components added as needed, in an organic solvent, may be used. There is no particular limitation on the temperature or time for the mixing. After the mixing, filtration may be performed, if necessary or desirable.

The content of the ionic salt (or, if two or more types are used, the total amount thereof) in the radiation-sensitive resist composition may be about 0.5 mass % or more to about 30 mass % or less, more particularly, about 2 mass % or more to about 20 mass % or less with respect to 100 mass % of the total mass of the composition.

<Pattern Forming Method>

The pattern forming method using the radiation-sensitive resist composition according to some example embodiments is not particularly limited. However, according to some example embodiments, the pattern forming method includes the processes of: coating the radiation-sensitive resist composition onto a substrate to form a resist film (hereinafter, referred to as “coating process”); exposing the resist film formed by the coating process (hereinafter, referred to as “exposure process”); and developing the exposed resist film (hereinafter, referred to as “development process”). Since the pattern forming method utilizes the radiation-sensitive resist composition, patterns with improved sensitivity, improved development properties, and/or improved resolution can be provided. Hereinbelow, each process will be described in detail.

[Coating Process]

In the coating process, the radiation-sensitive resist composition is coated onto one side (e.g., a top side) of a substrate to form a resist film. The coating method is not particularly limited and may include coating methods such as one or more of spin coating, spray coating, dip coating, knife-edge coating, inkjet printing, screen printing, and the like. Examples of the substrate include a silicon wafer, a wafer coated with aluminum, and the like. In particular, after coating the radiation-sensitive resist composition such that the film obtained therefrom has a predetermined thickness, prebaking (PB) may be performed if necessary or desirable, to evaporate solvents from the film.

The lower limit of resist film thickness post-PB may be 1 nm or more, specifically, 5 nm or more, and more specifically, 10 nm or more. In addition, the upper limit of resist film thickness post-PB may be 1,000 nm or less, specifically, 200 nm or less, and more specifically, 100 nm or less.

The lower limit of PB temperature may be 60° C. or more, in particular, 80° C. or more. In addition, the upper limit of PB temperature may be 150° C. or less, in particular, 140° C. or less. The lower limit of PB time may be 5 seconds or more, in particular, 10 seconds or more. The upper limit of PB time may be 600 seconds or less, in particular, 300 seconds or less.

[Exposure Process]

In the exposure process, the film formed by the coating process is exposed. This exposure in some cases may be performed by exposure to radiation through a mask having a predetermined pattern, using liquid such as water as a medium. Examples of the radiation include electromagnetic radiation such as visible light, ultraviolet light, far ultraviolet light, extreme ultraviolet light (EUV, wavelength 13.5 nm), X-rays, γ rays, etc.; a charged particle beam such as an electron beam (EM), α beam, and the like. Exposure to such radiation may be generally referred to as “exposure”.

Among these forms of radiation, the radiation used for exposure may be radiation in which relatively more secondary electrons are released from a metal atom included in a polyvalent ion (a) by exposure, and in particular, may be extreme ultraviolet light (EUV) or an electron beam.

Examples of such an exposure light source include: laser radiation in the ultraviolet region, such as KrF excimer laser (wavelength 248 nm), ArF excimer laser (wavelength 193 nm), and F2 excimer laser (wavelength 157 nm); harmonic laser radiation in the far-infrared region or vacuum ultraviolet region, through wavelength conversion from laser light from solid-state laser light sources (YAG or semiconductor laser, etc.); and an electron beam or extreme ultraviolet (EUV) radiation, and the like. During exposure, exposure is commonly performed through a mask corresponding to a desired pattern, but if the exposure light source is an electron beam, exposure may be achieved by direct writing without using a mask.

When using extreme ultraviolet radiation as the radiation source, the radiation integral dose may be, for example, about 2,000 mJ/cm² or less, particularly about 500 mJ/cm² or less. Alternatively, when using an electron beam as the radiation source, the integral radiation dose may be about 5,000 μC/cm² (micro-Coulombs/square centimeter) or less, particularly, about 1,000 μC/cm² or less.

After exposure, post-exposure bake (PEB) may be performed. The lower limit of PEB temperature may be about 50° C. or more, particularly, about 80° C. or more. The upper limit of PEB temperature may be about 180° C. or less, particularly, about 130° C. or less. The lower limit of PEB time may be about 5 seconds or more, particularly, about 10 seconds or more. The upper limit of PEB time may be about 600 seconds or less, particularly, about 300 seconds or less.

As described herein, in order to improve or maximize the performance of the radiation-sensitive resist composition, for example, an organic or inorganic anti-reflection film may be formed on the substrate. Alternatively or additionally, in order to prevent or reduce the likelihood of and/or impact from alkaline impurities, etc. introduced during the process from exerting adverse effects, for example, a protective film may be provided on the coating film. Alternatively or additionally, if immersion lithography is to be performed, for example, an immersion protective film may be provided on the resist film to prevent or reduce the likelihood of and/or impact from direct contact between immersion media and the resist film.

[Development Process]

In the development process, the resist film exposed in the above exposure process is developed. Examples of the developer used in this development process include an alkali developer, a developer containing an organic solvent (hereinafter, referred to as “organic developer”), and the like. Examples of the development method include a dipping process, a puddle process, a spray process, a dynamic dispense process, and the like. The development temperature may be, for example, from about 5° C. or more to about 60° C. or less. The developing time may be, for example, from about 5 seconds or more to about 300 seconds or less.

Examples of the alkali developer include an alkaline aqueous solution that has dissolved therein at least one alkaline compound selected from among sodium hydroxide, potassium hydroxide, sodium carbonate, sodium silicate, sodium metasilicate, ammonia water, ethylamine, n-propylamine, diethylamine, di-n-propyl amine, triethylamine, methyldiethylamine, ethyldimethylamine, triethanolamine, tetramethyl ammonium hydroxide (TMAH), pyrrole, piperidine, choline, 1,8-diazabicyclo[5.4.0]-7-undecene (DBU), 1,5-diazabicyclo[4.3.0]-5-nonene (DBN), and the like. The alkali developer may further include a surfactant.

The lower limit of the content of the alkaline compound in the alkali developer may be about 0.1 mass % or more, specifically about 0.5 mass % or more, and more specifically, about 1 mass % or more. In addition, the upper limit of the content of the alkali compound in the alkali developer may be about 20 mass % or less, specifically about 10 mass % or less, and more specifically, about 5 mass % or less.

After development, the resist pattern may be washed with distilled water, and subsequently, water remaining on the substrate and pattern may be removed.

For the organic solvent included in the organic developer, the same organic solvent presented as an example in <Organic Solvent> under [Radiation-sensitive Resist Composition] section above may be used.

The lower limit of the content of the organic solvent in the organic developer may be about 80 mass % or more, specifically, about 90 mass % or more, and more specifically, about 95 mass % or more, and in particular, may be about 99 mass % or more.

The organic developer may include a surfactant. In addition, the organic developer may contain a trace amount of moisture. In addition, during the development, the organic developer may be substituted with another type of solvent to thereby stop the development.

The resist pattern after development may be further washed. As a washing solution, distilled water, a rinsing solution, etc. may be used. The rinsing solution is not particularly limited as long as the solution does not dissolve resist patterns, and may be a solution containing a common organic solvent. Examples of the rinsing solution include an alcohol-based solvent and an ester-based solvent. After washing, the rinsing solution remaining on the substrate and patterns may be removed. In particular, when distilled water was used, water residues on the substrate and pattern may be removed.

In addition, the developer used may be one type or a combination of two or more types.

After the resist pattern is formed as described above, a patterned wiring substrate may be obtained, for example, by etching. The etching may be performed by various methods, such as dry etching using plasma gas, and/or wet etching for example by an alkaline solution, a copper(II) chloride solution, an iron(II) chloride solution, and the like.

After the resist pattern is formed, plating may be performed. The plating method is not particularly limited and includes one or more of copper plating, solder plating, nickel plating, gold plating, and the like.

Resist pattern residues after etching may be stripped by one or more organic solvents. Examples of such organic solvents are not particularly limited and may include one or more of propylene glycol monomethyl ether acetate (PGMEA), propylene glycol monomethyl ether (PGME), ethyl lactate (EL), and the like. The stripping method is not particularly limited and may include one or more a dipping method, a spray method, and the like. In addition, a wiring board having the resist pattern formed thereon may be a multilayer wiring board and may have a small-diameter via hole.

In some example embodiments, the wiring board may be formed by a lift-off method that deposits metal under vacuum after a resist pattern is formed, and then dissolves the resist pattern with solutions.

<Uses>

The radiation-sensitive resist composition may be a resist composition for one or more of krypton-fluorine (KrF) excimer laser exposure, a resist composition for argon-fluorine ArF excimer laser exposure, a resist composition for electron beam exposure, or a resist composition for EUV exposure. In particular, the radiation-sensitive resist composition may be a resist composition for electron beam exposure or a resist composition for EUV exposure, and may be used for microprocessing of semiconductors.

### EXAMPLES

The present disclosure will be described in greater detail through examples and comparative examples, but the technical scope of the present disclosure is not limited to the following examples. In addition, analyses were performed by the following methods.

[Methods of Analysis]

(X-Ray Power Diffraction Measurement)

X-ray power diffraction was performed using an X-ray diffractometer (Bruker Corp., D8-Advance, X-ray source: CuKα, power: 40 kV-40 mA).

(Fourier Transform Infrared Spectroscopy (FT-IR) Measurement)

Fourier-transform infrared spectroscopy spectra were obtained by the ATR technique using a Fourier-transform infrared spectrometer (Thermo Scientific, Nicolet iS10).

(Measurement of the Content of Element Bi (Elemental Analysis))

Using an energy-dispersive X-ray spectrometer (HORIBA Ltd., EMAX Evolution), 6 elements Bi, C, N, S, F, and O in a compound were measured, and using the sum of the 6 elements as 100 mass %, the content of element Bi (mass %) was obtained.

### Synthesis Example 1: Synthesis of Compound 1 {[Bi₆O₅(OH)₃(NO₃)₃]₂}⁴⁺-4NO₃⁻

Compound 1 was synthesized following the synthesis process disclosed in Acta Cryst. (1978). B34, 3169-3173. In particular, 10.000 g (20.51 mmol) of bismuth acetate pentahydrate (product of Fujifilm Wako Junyaku Inc.) and 14.950 g of 60% acetate (product of Fujifilm Wako Junyaku Inc.) were placed in a 2 L beaker and stirred, and then diluted with 990 mL of distilled water. After stirring for 15 minutes, 4% sodium hydroxide aqueous solution was added, and the reaction solution was adjusted to a pH of 1.5. During the dropwise addition of the sodium hydroxide aqueous solution, white precipitates were formed. Then, after stirring for 1 hour, the precipitates were isolated by vacuum filtration using a paper filter. Solids were washed with distilled water and then dried at 60° C. under vacuum for 10 hours, to yield 5.785 g of Compound 1 as white powder.

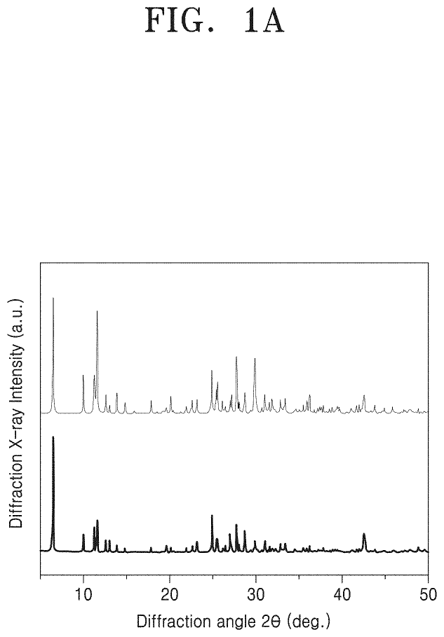

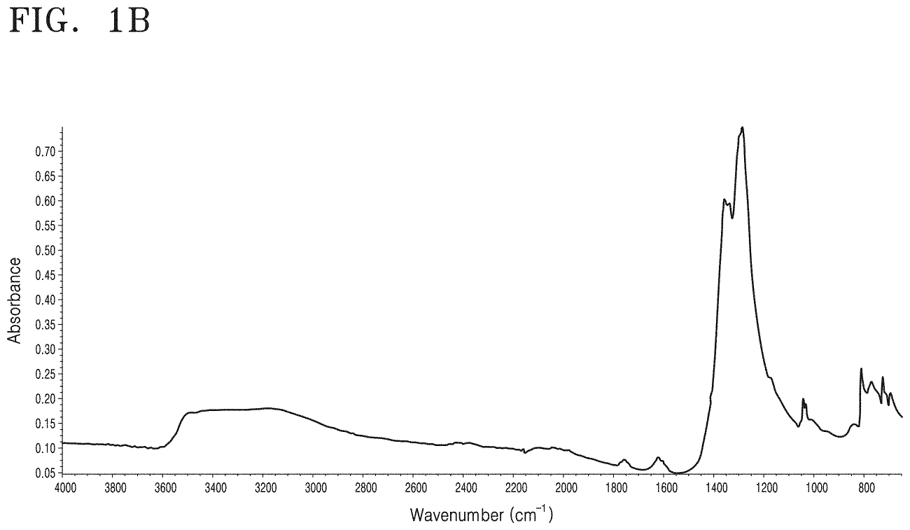

The identification of Compound 1 was performed by X-ray power diffraction. The crystal structure of Compound 1 was registered as CCDC 1592300 in Cambridge Structural Database (CSD, HP: https:bwww.cedc.cam.ac.uk), the entire contents of which are incorporated by reference. FIG. 1A shows the X-ray power diffraction pattern of Compound 1 synthesized above (bottom) and the X-ray power diffraction pattern simulated using the reported crystal structure data above (top). From these two patterns being nearly identical, it could be confirmed that Compound 1 obtained is the compound registered as CCDC 1592300.

In addition, the FT-IR spectrum of Compound 1 obtained is shown in FIG. 1B.

In addition, although in Acta Cryst. (1978). B34, 3169-3173, the entire contents of which are incorporated by reference, Compound 1 is represented as [Bi₆O₅(OH)₃]₊-5NO₃⁻, in Inorg. Chem. 2012, 51, 9376-9384, Compound 1 is disclosed as dimeric structure {[Bi₆O₅(OH)₃(NO₃)₃]₂}⁴⁺-4NO₃⁻.

### Synthesis Example 2: Synthesis of Compound 2 [Bi₉O₈(OH)₆]⁵⁺-5CF₃SO₃⁻

Compound 2 was synthesized following the synthesis process disclosed in RSC Adv., 2015, 5, 2914. In particular, 1.053 g (0.208 mmol) of bismuth(III) oxide (product of Fujifilm Wako Junyaku Inc.), 0.680 g (0.417 mmol) of trifluoromethanesulfonic acid (product of Fujifilm Wako Junyaku Inc.), and 16.3 mL of distilled water were placed in a polytetrafluoroethylene (PTFE) beaker and stirred for 10 minutes by a magnetic stirrer. The mixture had a pH of 0.9. Then, 28-30% ammonia water (product of Fujifilm Wako Junyaku Inc.) was dropwise added to adjust the pH of the mixture to 3.1. The mixture solution thus obtained was sealed in a 25 mL capacity high-pressure reaction vessel manufactured by SAN-Al Kagaku Co. LTD. The sealed reaction vessel was placed in a constant-temperature bath and heated at 175° C. for 48 hours, and then cooled to room temperature (25° C.). Precipitates in the reaction solution were isolated by filtration to yield 1.010 g of Compound 2 in a crystal form.

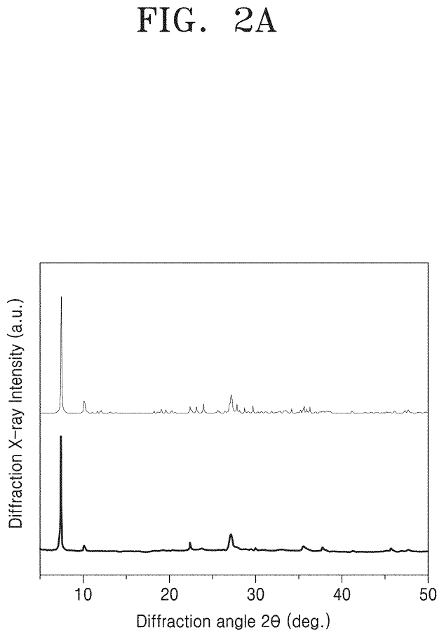

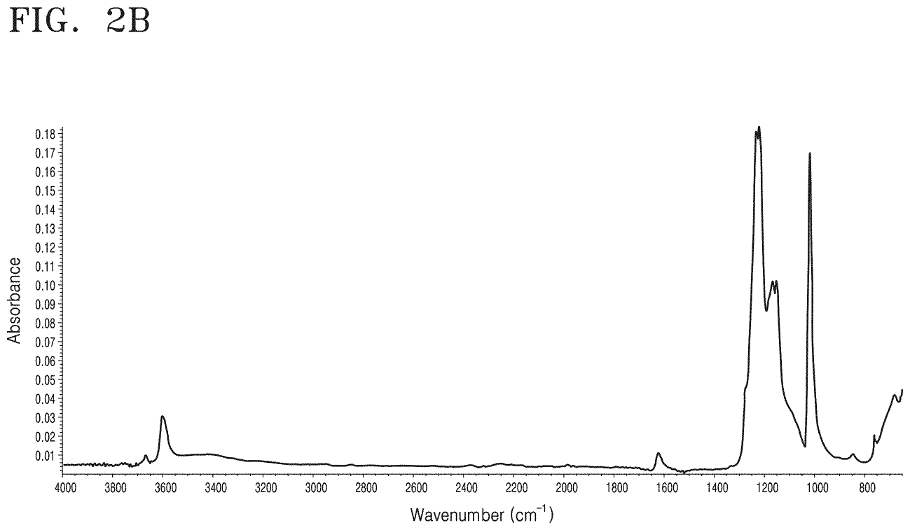

The identification of Compound 2, as with Compound 1, was performed by X-ray power diffraction. The crystal structure of Compound 2 is registered as CCDC 788955. FIG. 2A shows the X-ray power diffraction pattern of Compound 2 synthesized above (bottom) and the X-ray power diffraction pattern simulated using the reported crystal structure data above (top). Since these two patterns are nearly identical, it could be confirmed that Compound 2 obtained is the compound registered as CCDC 788955.

Also, the FT-IR spectrum of Compound 2 obtained is shown in FIG. 2B.

### Synthesis Example 3: Synthesis of Compound 3 {[Bi₆O₅(OH)₃(NO₃)₃]₂}⁴⁺-4(4-propoxycinnamate anion)

(Synthesis of Sodium 4-Propoxycinnamate)

In a 50 ml branched flask, 1.650 g (8 mmol) of 4-propoxycinnamic acid (product of Tokyo Kasei Kogyo Co., Ltd.) was placed, and a sodium hydroxide aqueous solution of 0.320 g (8 mmol) of sodium hydroxide (product of Tokyo Kasei Kogyo Co., Ltd.) dissolved in 20 mL of distilled water was dropwise added thereto under stirring, to yield a colorless, clear aqueous solution of sodium 4-propoxy cinnamate. After removing water by using an evaporator and a vacuum dryer, 1.826 g of sodium 4-propoxy cinnamate was obtained.

### (Synthesis of Compound 3 {[Bi₆O₅(OH)₃(NO₃)₃]₂}⁴⁺-4(4-propoxycinnamate anion)

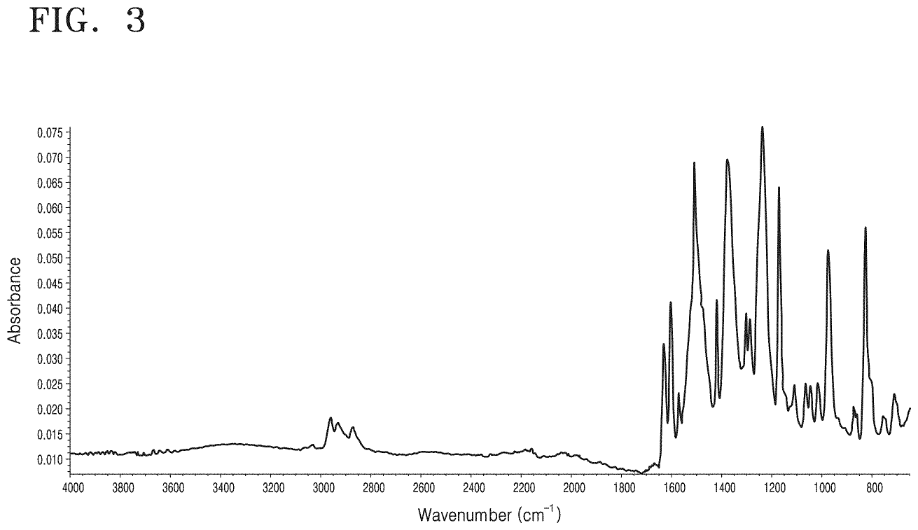

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution warmed to 70° C., containing 0.456 g (2 mmol) of sodium 4-propoxy cinnamate, 40.000 g of DMSO, and 40.000 g of distilled water was dropwise added under stirring and allowed to react at 25° C. for 1 hour to yield a solution with white precipitates formed therein. Using a centrifuge, the precipitates were separated from liquid. The precipitates were dispersed in 40 mL of distilled water and centrifuged to wash the precipitates, and this process was repeated 3 times. Then, after removing moisture by vacuum drying, 0.750 g of Compound 3 was obtained as white powder. From the result of FT-IR analysis (see FIG. 3), it was confirmed that the anionic portion of Compound 1, nitrate ion, was replaced with 4-propoxy cinnamate ion. In addition, from the measurement result of element analysis, it was confirmed that the content of element Bi (mass %) is nearly identical to its theoretical value, indicating that Compound 3 was obtained.

### Synthesis Example 4: Synthesis of Compound 4 [Bi₉O₈(OH)₆]⁵⁺-5(4-propoxycinnamate anion)

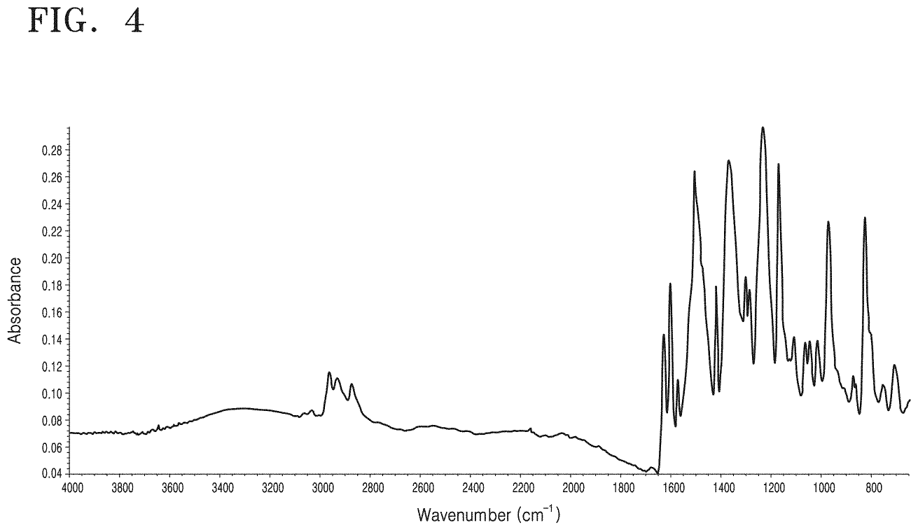

Solution of Compound 2 was prepared by mixing 0.559 g (0.2 mmol) of Compound 2 obtained in Synthesis Example 2 and 13.981 g of dimethylsulfoxide (DMSO) in a glass beaker. To this mixture, a solution heated to 70° C., containing 0.456 g (2 mmol) of sodium 4-propoxycinnamate, 40.000 g of DMSO, and 40.000 g of distilled water, was dropwise added under stirring and was allowed to react for 1 hour at 25° C. to produce a solution with white precipitates formed therein. Using a centrifuge, the precipitates were separated from liquid. The precipitates were dispersed in 40 mL of distilled water and centrifuged to wash the precipitates, and this process was repeated 3 times. Then, the precipitates were dehydrated by vacuum drying to yield 0.452 g of Compound 4 in a white powder form. From the result of FT-IR analysis (see FIG. 4), it was confirmed that the anionic portion of Compound 2, trifluoromethanesulfonate ion, was replaced with a 4-propoxy cinnamate ion. Also, from the measurement result of element analysis, which indicates that the content (mass %) of element Bi is nearly identical to its theoretical value, it was confirmed that Compound 4 was obtained.

### Synthesis Example 5: Synthesis of Compound 5 {[Bi₆O₅(OH)₃(NO₃)₃]₂}⁴⁺-4(9,10-dimethoxyanthracene-2-sulfonate anion)

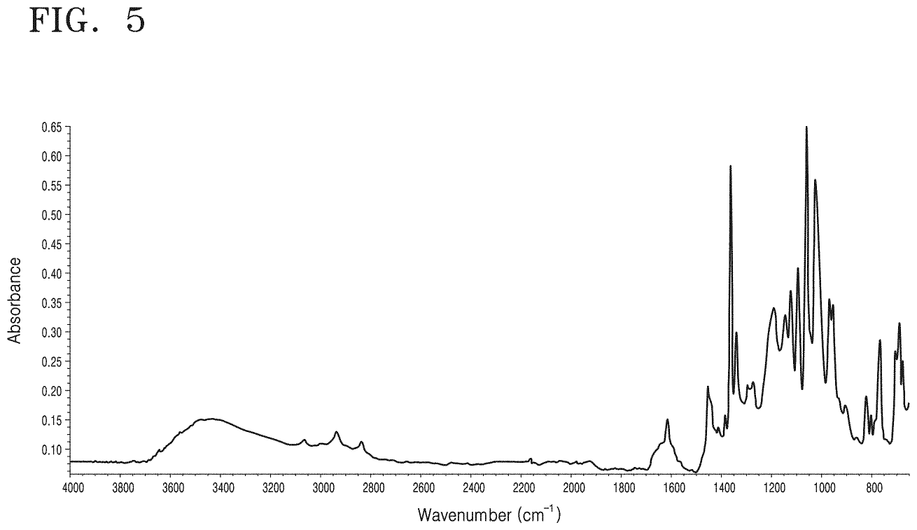

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution containing 0.681 g (2 mmol) of 9,10-dimethoxyanthracene-2-sulfonic acid (product of Tokyo Kasei Kogyo Co., Ltd.), 17.490 g of DMSO, and 1.749 g of distilled water was dropwise added under stirring and allowed to react at 25° C. for 1 hour. Then, 17.490 g of distilled water was dropwise added thereto to produce a solution with orange-colored precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.710 g of Compound 5 was obtained as orange-colored powder. From the result of FT-IR analysis (see FIG. 5), it was confirmed that the anionic portion of Compound 1, nitrate ion, was replaced with a 9,10-dimethoxyanthracene-2-sulfonate anion. Also, from the measurement result of element analysis, which indicates that the content (mass %) of element Bi is nearly identical to its theoretical value, it was confirmed that Compound 5 was obtained.

### Synthesis Example 6: Synthesis of Compound 6 [Bi₉O₈(OH)₆]⁵⁺-5(9,10-dimethoxyanthracene-2-sulfonate anion)

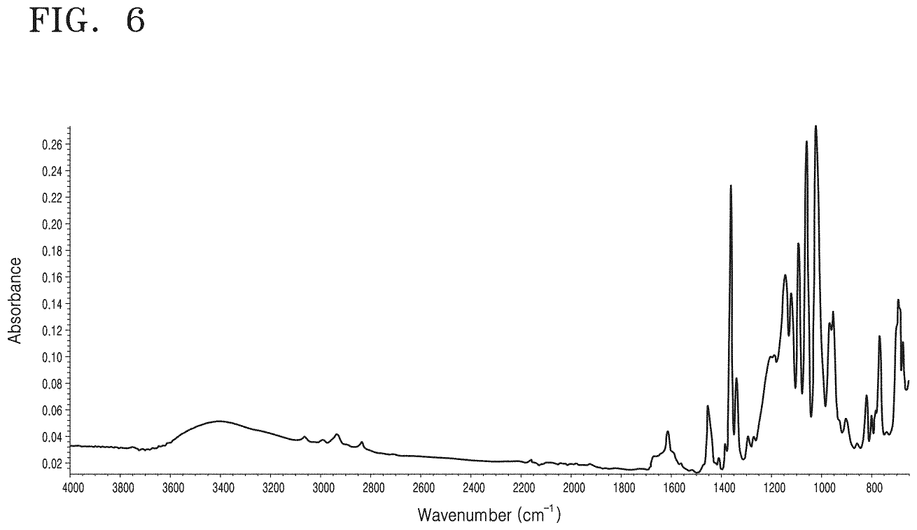

Solution of Compound 2 was prepared by mixing 0.559 g (0.2 mmol) of Compound 2 obtained in Synthesis Example 2 and 13.981 g of dimethylsulfoxide (DMSO) in a glass beaker. To this mixture, a solution containing 0.681 g (2 mmol) of 9,10-dimethoxyanthracene-2-sulfonic acid (product of Tokyo Kasei Kogyo Co., Ltd.), 13.981 g of DMSO, and 1.398 g of distilled water was dropwise added under stirring and allowed to react at 25° C. for 1 hour. Then, 13.981 g of distilled water was dropwise added thereto to produce a solution with orange-colored precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.663 g of Compound 6 was obtained as orange-colored powder. From the result of FT-IR analysis (see FIG. 6), it was confirmed that the anionic portion of Compound 2, trifluoromethanesulfonate ion, was replaced with 9,10-dimethoxyanthracene-2-sulfonate anion. In addition, from the measurement result of element analysis, it was confirmed that the content of element Bi (mass %) is nearly identical to its theoretical value, indicating that Compound 6 was obtained.

### Synthesis Example 7: Synthesis of Compound 7 {[Bi₆O₅(OH)₃(NO₃)₃]₂}⁴⁻-4(anthraquinone-2-sulfonic acid anion)

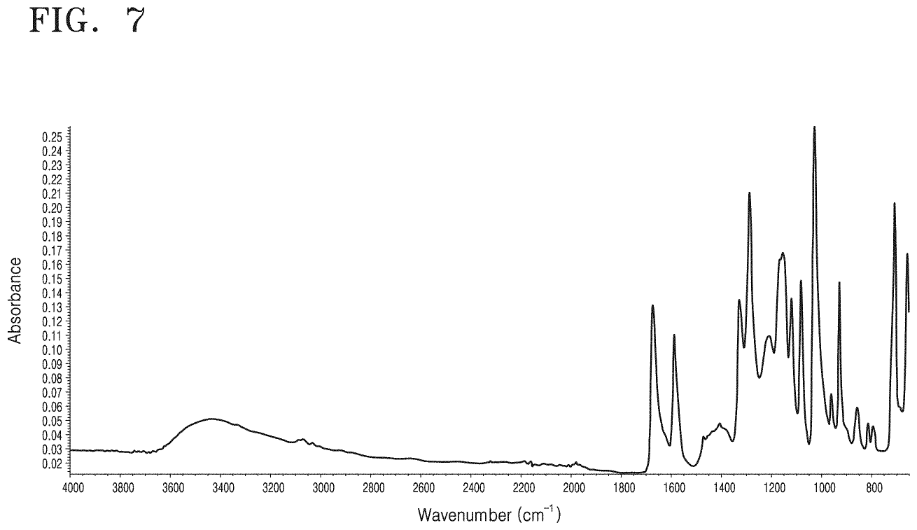

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution containing 0.657 g (2 mmol) of sodium anthraquinone-2-sulfonate monohydrate (product of Tokyo Kasei Kogyo Co., Ltd.), 17.490 g of DMSO, and 1.749 g of distilled water was dropwise added under stirring and allowed to react at 25° C. for 1 hour. Then, 8.745 g of distilled water was dropwise added thereto to produce a solution with yellow-colored precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.651 g of Compound 7 was obtained as yellow powder. From the result of FT-IR analysis (see FIG. 7), it was confirmed that the anionic portion of Compound 1, nitrate ion, was replaced with anthraquinone-2-sulfonate anion. In addition, from the measurement result of element analysis, it was confirmed that the content of element Bi (mass %) is nearly identical to its theoretical value, indicating that Compound 7 was obtained.

### Synthesis Example 8: Synthesis of Compound 8 [Bi₉O₈(OH)₆]⁵⁺-5(anthraquinone-2-sulfonate anion)

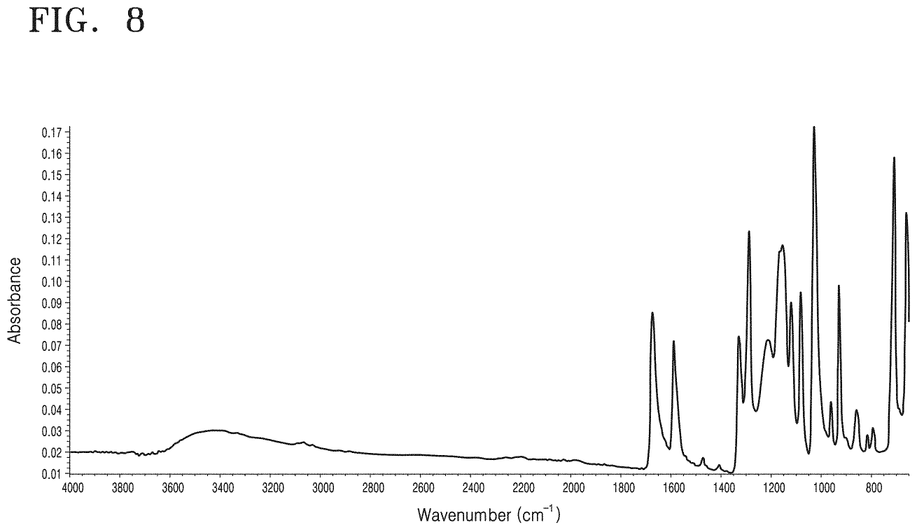

Solution of Compound 2 was prepared by mixing 0.559 g (0.2 mmol) of Compound 2 obtained in Synthesis Example 2 and 13.981 g of dimethylsulfoxide (DMSO) in a glass beaker. To this mixture, a solution containing 0.657 g (2 mmol) of sodium anthraquinone-2-sulfonate monohydrate (Tokyo Kasei Kogyo Co., Ltd.), 13.981 g of DMSO, and 1.398 g of distilled water was dropwise added under stirring and allowed to react at 25° C. for 1 hour. Then, 6.991 g of distilled water was dropwise added thereto to produce a solution with yellow precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.571 g of Compound 8 was obtained as yellow powder. From the result of FT-IR analysis (see FIG. 8), it was confirmed that the anionic portion of Compound 1, nitrate ion, was replaced with anthraquinone-2-sulfonate ion. In addition, from the measurement result of element analysis, which indicates the content of element Bi (mass %) is nearly identical to its theoretical value, it was confirmed that Compound 8 was obtained.

### Synthesis Example 9: Synthesis of Compound 9 {[Bi₆O₅(OH)₃(NO₃)₃]₂}⁴⁺-4(4-azidobenzoate anion)

(Synthesis of Sodium 4-Azidobenzoate)

In a 50 ml branched flask, 1.305 g (8 mmol) of 4-azidobenzoic acid (product of Tokyo Kasei Kogyo Co., Ltd.) was placed, and a sodium hydroxide aqueous solution of 0.320 g (8 mmol) of sodium hydroxide (product of Tokyo Kasei Kogyo Co., Ltd.) dissolved in 20 mL of distilled water was dropwise added thereto under stirring, to yield a brown-colored, clear aqueous solution of sodium 4-azidobenzoate. Using an evaporator and a vacuum dryer, water was removed to yield 1.620 g of sodium 4-azidobenzoate.

### Synthesis of Compound 9 {[Bi₆O₅(OH)₃(NO₃)₃]₂}⁴⁺-4(4-azidobenzoate anion))

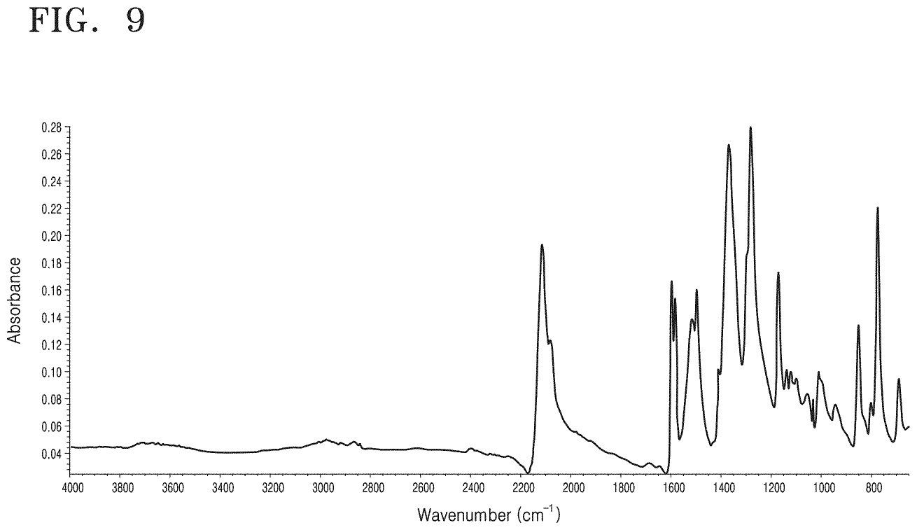

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution containing 0.370 g (2 mmol) of sodium 4-azidobenzoate, 17.490 g of DMSO, and 1.749 g of distilled water was dropwise added under stirring and allowed to react at 25° C. for 1 hour, to produce a solution with white precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.403 g of Compound 13 was obtained as white powder. From the result of FT-IR analysis (see FIG. 9), it was confirmed that the anionic portion of Compound 1, nitrate ion, was replaced with 4-azidobenzoate ion. Also, from the measurement result of element analysis, which indicates that the content (mass %) of element Bi is nearly identical to its theoretical value, it was confirmed that Compound 9 was obtained.

### Synthesis Example 10: Synthesis of Compound 10 [Bi₉O₈(OH)₆]⁵⁺-5(4-azidobenzoate anion)

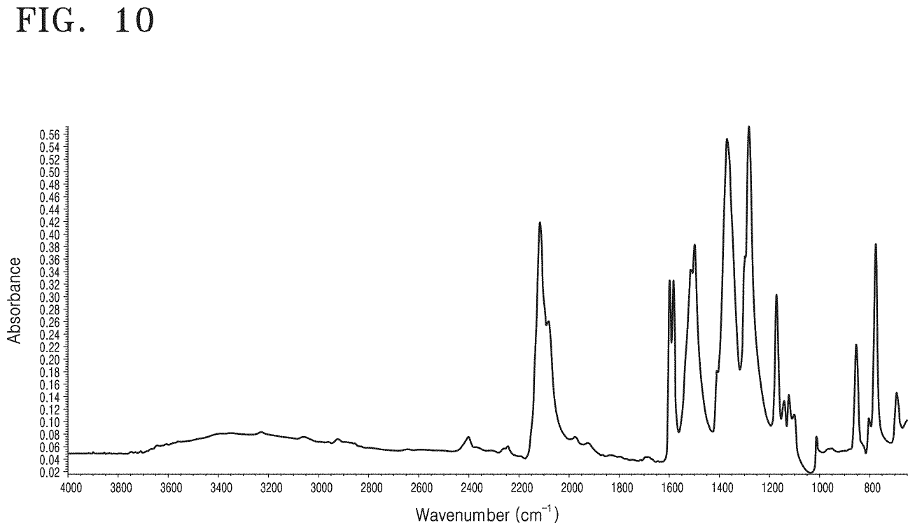

Solution of Compound 2 was prepared by mixing 0.559 g (0.2 mmol) of Compound 2 obtained in Synthesis Example 2 and 13.981 g of dimethylsulfoxide (DMSO) in a glass beaker. To this mixture, a solution containing 0.370 g (2 mmol) of sodium 4-azidobenzoate, 13.981 g of DMSO, and 1.398 g of distilled water was dropwise added under stirring and allowed to react at 25° C. for 1 hour, to produce a solution with white precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.376 g of Compound 10 was obtained as white powder. From the result of FT-IR analysis (see FIG. 10), it was confirmed that the anionic portion of Compound 1, nitrate ion, was replaced with 4-azidobenzoate ion. In addition, from the measurement result of element analysis, it was confirmed that the content of element Bi (mass %) is nearly identical to its theoretical value, indicating that Compound 10 was obtained.

### Synthesis Example 11: Synthesis of Compound 11 [Bi₉O₈(OH)₆]⁵⁺-5(6-maleimide hexanoate anion)

(Synthesis of Sodium 6-Maleimide Hexanoate)

In a 50 ml branched flask, 1.650 g (8 mmol) of 6-maleimidehexanoic acid (product of Tokyo Kasei Kogyo Co., Ltd.) was placed, and a sodium hydroxide aqueous solution of 0.320 g (8 mmol) of sodium hydroxide (product of Tokyo Kasei Kogyo Co., Ltd.) dissolved in 32 mL of distilled water and 20.8 g of 2-propanol was dropwise added thereto under stirring, to yield a colorless, clear solution of sodium 6-maleimide hexanoate. Water and 2-propanol were removed using an evaporator and a vacuum dryer, to yield 1.820 g of sodium 6-maleimide hexanoate.

### Synthesis of Compound 11 {[Bi₆O₅(OH)₃(NO₃)₃]₂}⁴⁺-4(6-maleimide hexanoate anion)

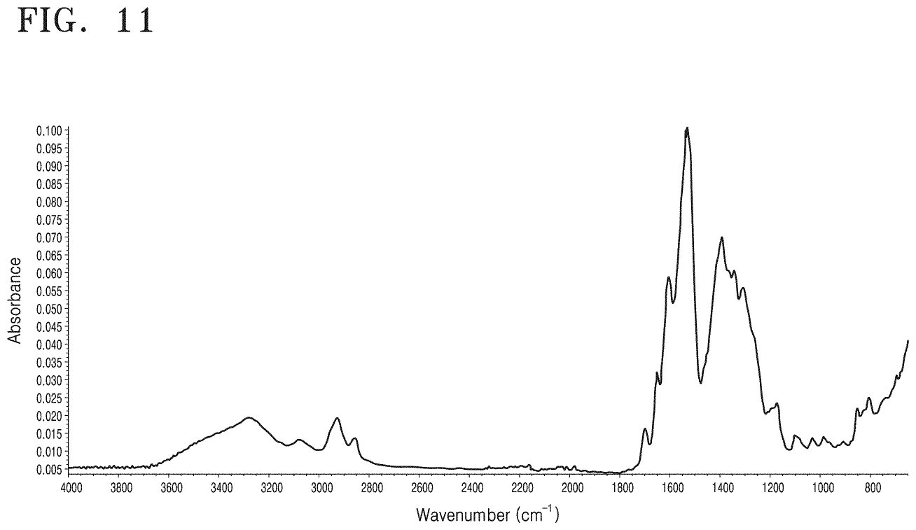

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution containing 0.456 g of sodium 6-maleimide hexanoate, 17.490 g of DMSO, and 1.749 g of distilled water was dropwise added under stirring and allowed to react at 25° C. for 1 hour. Then, 8.745 g of distilled water was dropwise added thereto to produce a solution with white precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.383 g of Compound 13 was obtained as white powder. From the result of FT-IR analysis (see FIG. 11), it was confirmed that the anionic portion of Compound 1, nitrate ion, was replaced with 6-maleimide hexanoate ion. From the measurement result of element analysis, which indicates that the content of element Bi (mass %) matches the calculated value, it was confirmed that Compound 11 was obtained.

### Synthesis Example 12: Synthesis of Compound 12 [Bi₉O₈(OH)₆]⁵⁺-5(6-maleimide hexanoate anion)

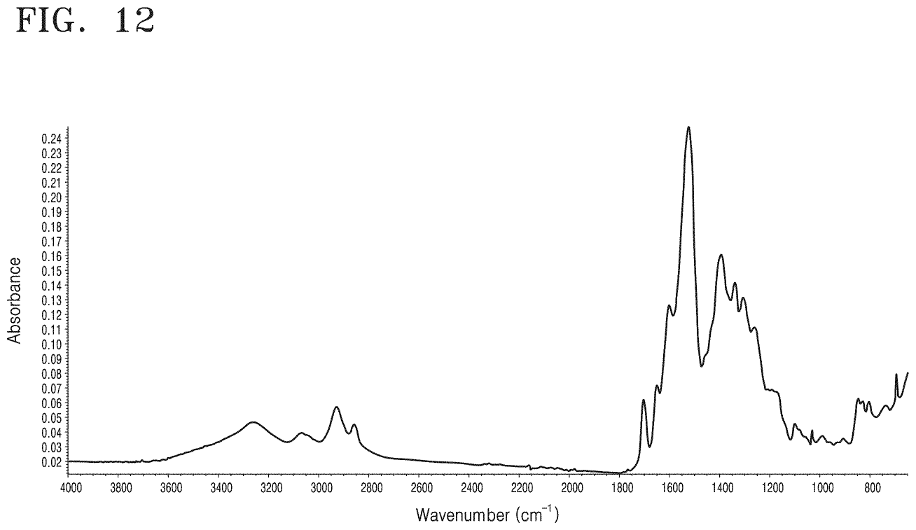

Solution of Compound 2 was prepared by mixing 0.559 g (0.2 mmol) of Compound 2 obtained in Synthesis Example 2 and 13.981 g of dimethylsulfoxide (DMSO) in a glass beaker. To this mixture, a solution containing 0.456 g (2 mmol) of sodium 6-maleimide hexanoate, 13.981 g of DMSO, and 1.398 g of distilled water was dropwise added under stirring and allowed to react at 25° C. for 1 hour. Then, 6.991 g of distilled water was dropwise added thereto to produce a solution with white precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.390 g of Compound 12 was obtained as white powder. From the result of FT-IR analysis (see FIG. 12), it was confirmed that the anionic portion of Compound 1, nitrate ion, was replaced with 6-maleimide hexanoate anion. Also, from the measurement result of element analysis, which indicates that the content (mass %) of element Bi is nearly identical to its theoretical value, it was confirmed that Compound 12 was obtained.

### Synthesis Example 13: Synthesis of Compound 13 {[Bi₆O₅(OH)₃(NO₃)₃]₂}⁴⁺-4(anthraquinone-1-sulfonate anion)

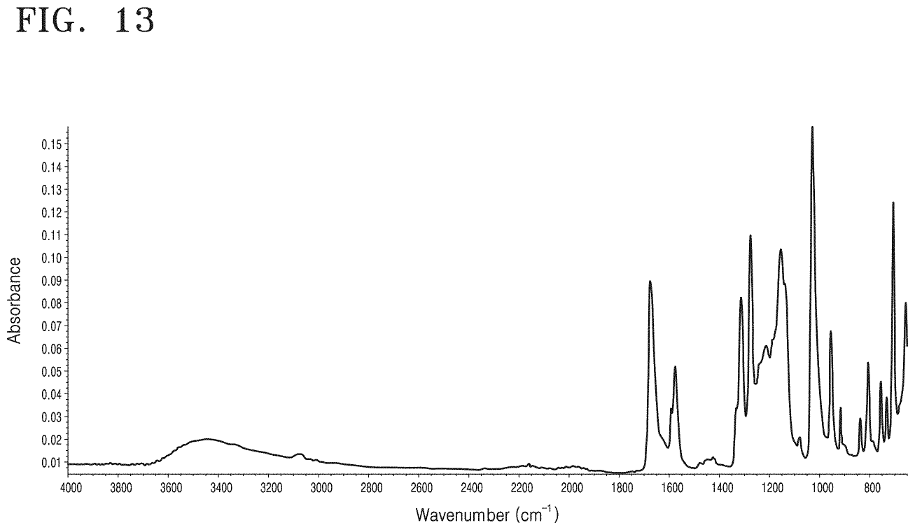

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution containing 0.621 g (2 mmol) of sodium anthraquinone-1-sulfonate (Tokyo Kasei Kogyo Co., Ltd.), 17.490 g of DMSO, and 1.749 g of distilled water was dropwise added under stirring and allowed to react at 25° C. for 1 hour. Then, 8.745 g of distilled water was dropwise added thereto to produce a solution with yellow-colored precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.652 g of Compound 13 was obtained as yellow powder. From the result of FT-IR analysis (see FIG. 13), it was confirmed that the anionic portion of Compound 1, nitrate ion, was replaced with anthraquinone-1-sulfonate anion. In addition, from the measurement result of element analysis, it was confirmed that the content of element Bi (mass %) is nearly identical to its theoretical value, indicating that Compound 13 was obtained.

### Synthesis Example 14: Synthesis of Compound 14 {[Bi₆O₅(OH)₃(NO₃)₃]₂}⁴⁺-4(2-((9,10-dihydro-4-(methylamino)-9-10-dioxo-1-anthracenyl)amino)-5-methyl benzenesulfonate anion)

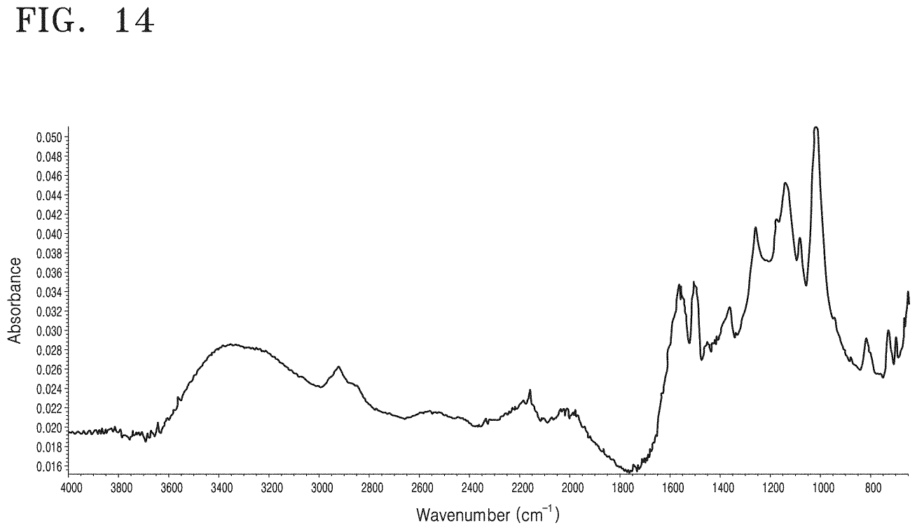

Solution of Compound 1 was prepared by mixing 0.700 g (0.2 mmol) of Compound 1 obtained in Synthesis Example 1 and 17.490 g of dimethylsulfoxide (DMSO) in a glass beaker. To this, a solution containing 0.889 g (2 mmol) of Alizarin Astrol (2-[[9,10-dihydro-4-(methylamino)-9,10-dioxo-1-anthracenyl]amino]-5-methyl-benzenesulfonic acid, monosodium salt, product of Tokyo Kasei Kogyo Co., Ltd.), 17.490 g of DMSO, and 1.749 g of distilled water was added dropwise under stirring and allowed to react at 25° C. for 1 hour. Then, 8.745 g of distilled water was dropwise added thereto to produce a solution with deep blue-colored precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.340 g of Compound 14 was obtained as deep blue-colored powder. From the result of FT-IR analysis (see FIG. 14), it was confirmed that the anionic portion of Compound 1, nitrate ion, was replaced with 2-((9,10-dihydro-4-(methylamino)-9-10-dioxo-1-anthracenyl)amino)-5-methyl benzenesulfonate ion. Also, from the measurement result of element analysis, which indicates that the content (mass %) of element Bi is nearly identical to its theoretical value, it was confirmed that Compound 14 was obtained.

### Synthesis Example 15: Synthesis of Compound 15 {[Bi₆O₅(OH)₃(NO₃)₃]₂}⁴⁺-4(naphthoquinone-2-diazide-5-sulfonate anion)

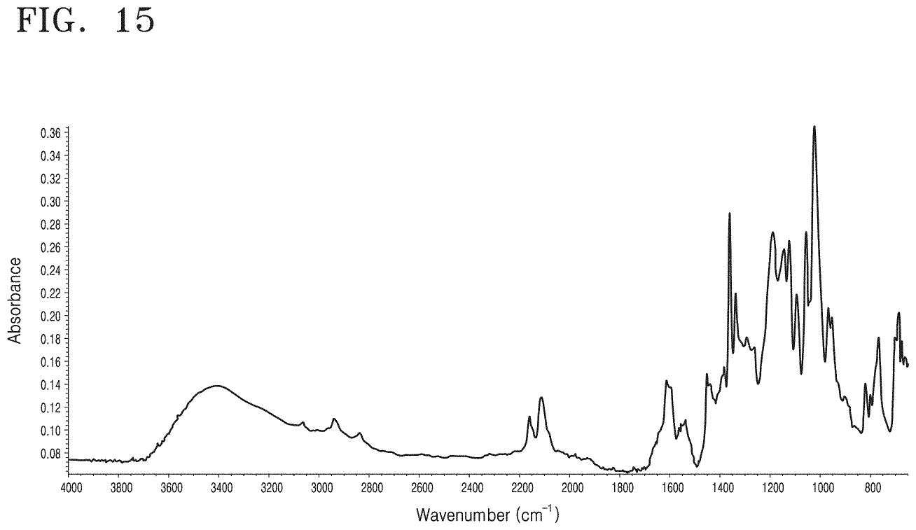

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution containing 0.544 g (2 mmol) of sodium naphthoquinone-2-diazide-5-sulfonate (product of Tokyo Kasei Kogyo Co., Ltd.), 17.490 g of DMSO, and 1.749 g of distilled water was dropwise added under stirring and allowed to react at 25° C. for 1 hour. Then, 34.980 g of distilled water was dropwise added thereto to produce a solution with yellow precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.211 g of Compound 15 was obtained as yellow powder. From the result of FT-IR analysis (see FIG. 15), it was confirmed that the anionic portion of Compound 1, nitrate ion, was replaced with naphthoquinone-2-diazide-5-sulfonate ion. Also, from the measurement result of element analysis, which indicates that the content (mass %) of element Bi is nearly identical to its theoretical value, it was confirmed that Compound 15 was obtained.

### Synthesis Example 16: Synthesis of Compound 16 {[Bi₆O₅(OH)₃(NO₃)₃]₂}⁴⁺-4(4-n-octyl benzenesulfonate anion)

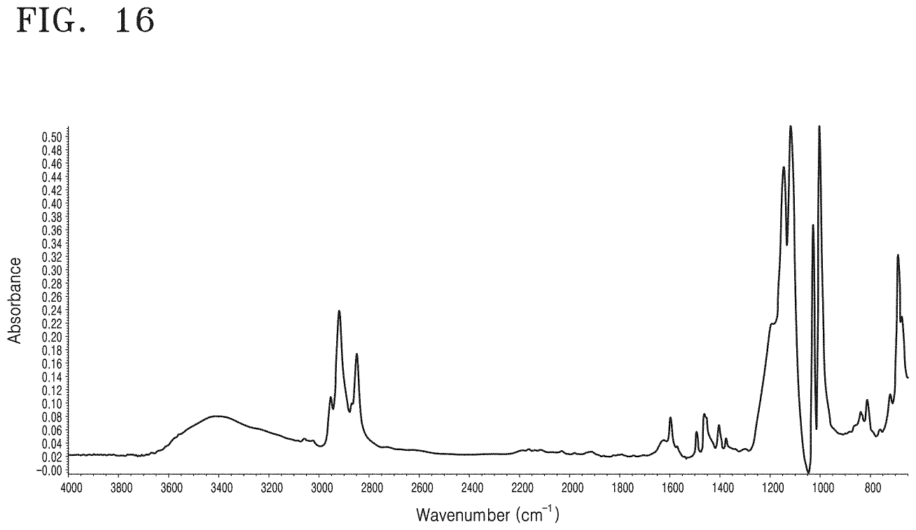

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution containing 0.585 g (2 mmol) of sodium 4-n-octyl benzene sulfonate (Tokyo Kasei Kogyo Co., Ltd.), 17.490 g of DMSO, and 1.749 g of distilled water was dropwise added under stirring and allowed to react at 25° C. for 1 hour. Then, 8.745 g of distilled water was dropwise added thereto to produce a solution with gold-colored precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.402 g of Compound 16 was obtained as white powder. From the result of FT-IR analysis (see FIG. 16), it was confirmed that the anionic portion of Compound 1, nitrate ion, was replaced with 4-n-octyl benzene sulfonate ion. In addition, from the measurement result of element analysis, it was confirmed that the content of element Bi (mass %) is nearly identical to its theoretical value, indicating that Compound 16 was obtained.

### Synthesis Example 17: Synthesis of Compound 17 {[Bi₆O₅(OH)₃(NO₃)₃]₂}⁴⁺-4(4-n-octyloxybenzoate anion)

(Synthesis of Sodium 4-n-Octyloxybenzoate)

In a 50 ml branched flask, 2.003 g (8 mmol) of 4-n-octyloxybenzoic acid (product of Tokyo Kasei Kogyo Co., Ltd.) was placed, and a sodium hydroxide aqueous solution of 0.320 g (8 mmol) of sodium hydroxide (product of Tokyo Kasei Kogyo Co., Ltd.) dissolved in 32 mL of distilled water and 20.8 g of 2-propanol was dropwise added thereto under stirring, to yield a colorless, clear solution of sodium 4-n-octyloxybenzoate. Water and 2-propanol were removed using an evaporator and a vacuum dryer to yield 2.175 g of sodium 4-n-octyloxybenzoate.

### Synthesis of Compound 17 {[Bi₆O₅(OH)₃(NO₃)₃]₂}⁴⁺-4(4-n-octyloxy benzoate anion)

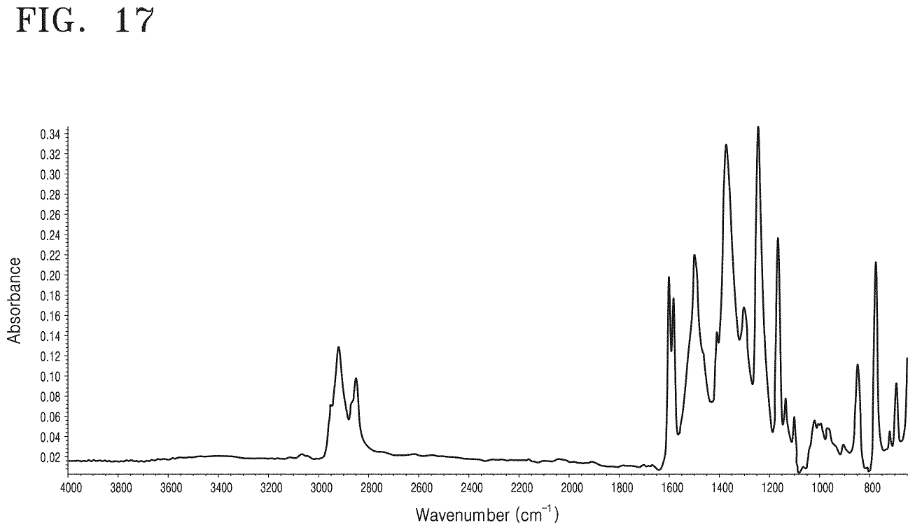

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution containing 0.545 g (2 mmol) of sodium 4-n-octyloxybenzoate, 17.490 g of DMSO, and 1.749 g of distilled water was dropwise added under stirring and allowed to react at 25° C. for 1 hour to produce a solution with white precipitates formed therein. Using a centrifuge, the precipitates were separated from liquid. The precipitates were dispersed in 40 mL of distilled water and centrifuged to wash the precipitates, and this process was repeated 3 times. Then, the precipitates were dehydrated by vacuum drying to yield 0.652 g of Compound 17 as yellow powder. From the result of FT-IR analysis (see FIG. 17), it was confirmed that the anionic portion of Compound 1, nitrate ion, was replaced with 4-n-octyloxy benzoate ion. In addition, from the measurement result of element analysis, which indicates that the content of element Bi (mass %) is nearly identical to its theoretical value, it was confirmed that Compound 17 was obtained.

### Synthesis Example 18: Synthesis of Compound 18 {[Bi₆O₅(OH)₃(NO₃)₃]₂}⁴⁺-4(ketoprofen anion)

(Synthesis of Ketoprofen Sodium)

In a 50 ml branched flask, 2.034 g (8 mmol) of ketoprofen (product of Tokyo Kasei Kogyo Co., Ltd.) was placed. Then, a sodium hydroxide aqueous solution of 0.320 g (8 mmol) of sodium hydroxide (product of Tokyo Kasei Kogyo Co., Ltd.) dissolved in 32 mL of distilled water was added dropwise thereto under stirring, to yield a colorless, clear aqueous solution of ketoprofen sodium. Water was removed using a vacuum dryer, and 2.203 g of ketoprofen sodium was obtained.

### (Synthesis of Compound 18 {[Bi₆O₅(OH)₃(NO₃)₃]₂}⁴⁺-4(ketoprofen anion))

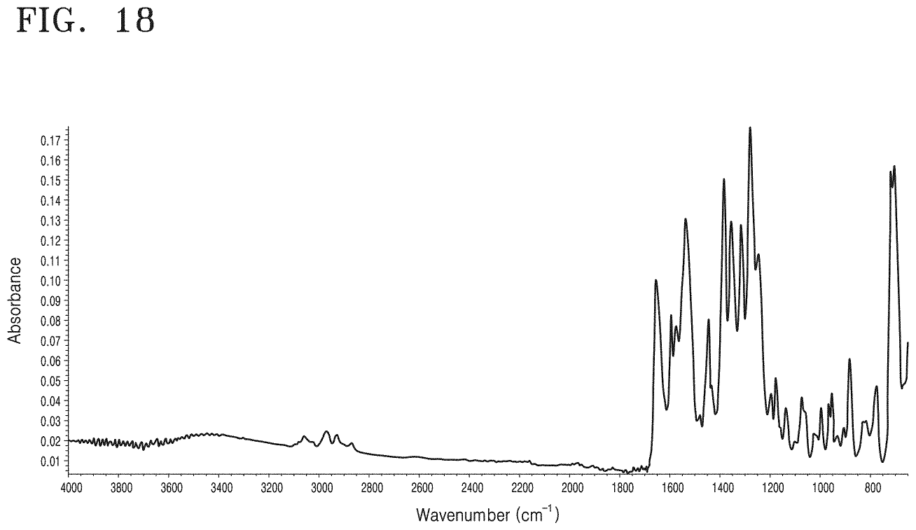

Solution of Compound 1 was prepared by mixing 0.700 g (0.2 mmol) of Compound 1 obtained in Synthesis Example 1 and 17.490 g of dimethylsulfoxide (DMSO) in a glass beaker. To this mixture, a solution containing 0.553 g (2 mmol) of ketoprofen sodium, 17.490 g of DMSO, and 1.749 g of distilled water was dropwise added under stirring and allowed to react at 25° C. for 1 hour. Then, 8.745 g of distilled water was dropwise added thereto to produce a solution with white precipitates formed therein. Using a centrifuge, the precipitates were separated from liquid. The precipitates were dispersed in 40 mL of distilled water and centrifuged to wash the precipitates, and this process was repeated 3 times. Then, moisture was removed by vacuum drying, and 0.760 g of Compound 18 was obtained as white powder. From the result of FT-IR analysis (see FIG. 18), it was confirmed that the anionic portion of Compound 1, nitrate ion, was replaced with ketoprofen ion. In addition, from the measurement result of element analysis, which indicates the content of element Bi (mass %) is nearly identical to its theoretical value, it was confirmed that Compound 18 was obtained.

### Synthesis Example 19: Synthesis of Compound 19 {[Bi₆O₅(OH)₃(NO₃)₃]₂}⁴⁺-4[mono(2-acryloyloxyethyl)succinate anion]

(Synthesis of sodium mono(2-acryloyloxyethyl)succinate)

In a 50 ml branched flask, 1.730 g (8 mmol) of mono(2-acryloyloxy ethyl) succinate (product of Tokyo Kasei Kogyo Co., Ltd.) was placed. Then, a sodium hydroxide aqueous solution of 0.320 g (8 mmol) of sodium hydroxide (product of Tokyo Kasei Kogyo Co., Ltd.) dissolved in 17.148 g of distilled water was added dropwise thereto under stirring, to yield a colorless, clear aqueous solution of sodium mono(2-acryloyloxy ethyl) succinate (10 mass % aqueous solution).

### (Synthesis of Compound 19 {[Bi₆O₅(OH)₃(NO₃)₃]₂}⁴⁺-4[mono (2-acryloyloxyethyl)succinate anion])

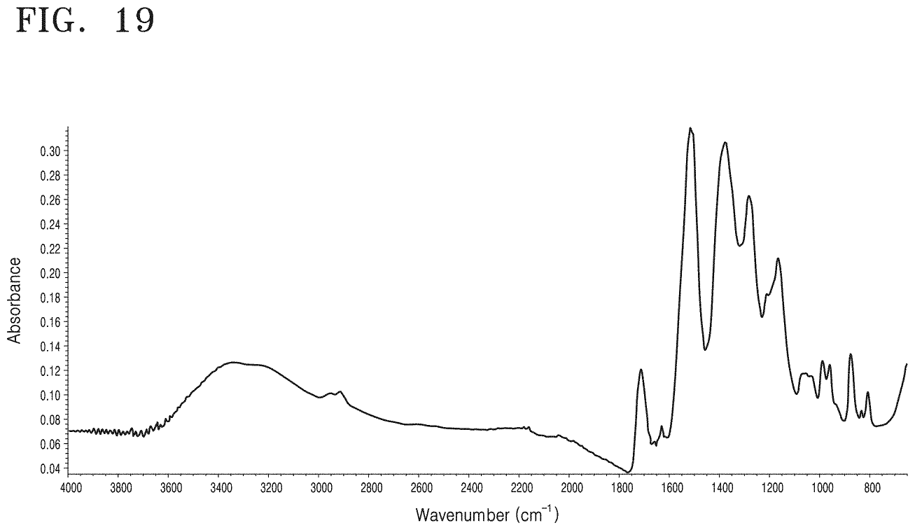

Solution of Compound 1 was prepared by mixing 0.700 g (0.2 mmol) of Compound 1 obtained in Synthesis Example 1 and 17.490 g of dimethylsulfoxide (DMSO) in a glass beaker. Then, 4.763 g (2 mmol) of 10 mass % aqueous solution of sodium mono(2-acryloyloxy ethyl) succinate was dropwise added under stirring and allowed to react at 25° C. for 1 hour. Then, 17.490 g of distilled water was dropwise added thereto to produce a solution with white precipitates formed therein. Using a centrifuge, the precipitates were separated from liquid. The precipitates were dispersed in 40 mL of distilled water and centrifuged to wash the precipitates, and this process was repeated 3 times. Then, moisture were removed by vacuum drying, and 0.245 g of Compound 19 was obtained as white powder. From the result of FT-IR analysis (see FIG. 19), it was confirmed that the anionic portion of Compound 1, nitrate ion, was replaced with monosuccinate(2-acryloyloxyethyl) ion. Also, from the measurement result of element analysis, which indicates that the content (mass %) of element Bi is nearly identical to its theoretical value, it was confirmed that Compound 19 was obtained.

### Synthesis Example 20: Synthesis of Compound 20 {[Bi₆O₅(OH)₃(NO₃)₃]₂}⁴⁺-4[3-(acryloyloxy)propane-1-sulfonate anion]

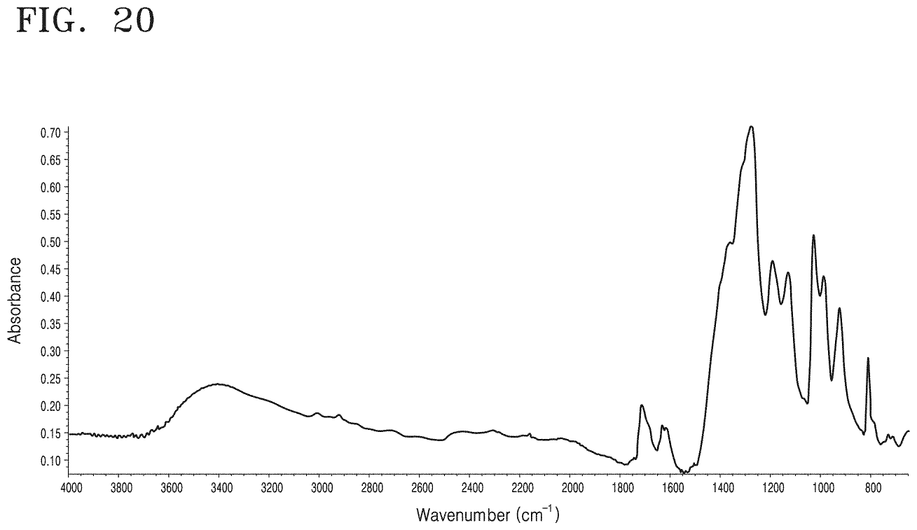

Solution of Compound 1 was prepared by mixing 0.700 g (0.2 mmol) of Compound 1 obtained in Synthesis Example 1 and 17.490 g of dimethylsulfoxide (DMSO) in a glass beaker. Then, 0.465 g (2 mmol) of potassium 3-(acryloyloxy)propane-1-sulfonate (product of Tokyo Kasei Kogyo Co., Ltd.) was added thereto under stirring and allowed to react at 25° C. for 1 hour. Then, 42.470 mL of distilled water was dropwise added thereto to produce a solution with white precipitates formed therein. Using a centrifuge, the precipitates were separated from liquid. The precipitates were dispersed in 40 mL of distilled water and centrifuged to wash the precipitates. Then, moisture was removed by vacuum drying, and 0.247 g of Compound 20 was obtained as white powder. From the result of FT-IR analysis (see FIG. 20), it was confirmed that the anionic portion of Compound 1, nitrate ion, was replaced with 3-(acryloyloxy)propane-1-sulfonate ion. In addition, from the measurement result of element analysis, it was confirmed that the content of element Bi (mass %) is nearly identical to its theoretical value, indicating that Compound 20 was obtained.

The result of element analysis of Compounds 1 to 20 is shown in Table 1 below.

TABLE 1

| | | Element Bi | Element Bi |
|---|---|---|---|
| | | Mass % | Mass % |
| | Top: Structural Formula | (theoretical | (measured |
| | Bottom: Molecular Formula | value) | value) |
| Compound 1 | {[Bi₆O₅(OH)₃(NO₃)₃]₂}⁴⁺•4NO_{₃}_{^{−}} | 73.8 | 76.2 |
| | Bi₁₂N₁₀H₁₈O₅₂ | | |
| Compound 2 | [Bi₉O₈(OH)₆]⁵⁺•5CF₃SO_{₃}_{^{−}} | 66.0 | 67.3 |
| | Bi₉C₅H₆S₅F₁₅O₂₉ | | |
| Compound 3 | {[Bi₆O₅(OH)₃(NO₃)₃]₂}⁴⁺•4(4- | 64.2 | 62.1 |
| | propoxycinnamate anion) | | |
| | Bi₁₂C₄₈N₆H₅₈O₄₆ | | |
| Compound 4 | [Bi₉O₈(OH)₆]⁵⁺•5(4-propoxycinnamate | 61.4 | 59.7 |
| | anion) | | |
| | Bi₉C₆₀H₇₁O₂₉ | | |
| Compound 5 | {[Bi₆O₅(OH)₃(NO₃)₃]₂}⁴⁺•4(9,10- | 57.6 | 53.2 |
| | dimethoxyanthracene-2-sulfonate anion) | | |
| | Bi₁₂C₆₄N₆H₅₈S₄O₅₄ | | |
| Compound 6 | [Bi₉O₈(OH)₆]⁵⁺•5(9,10- | 51.9 | 54.1 |
| | dimethoxyanthracene-2-sulfonate anion) | | |
| | Bi₉C₈₀H₇₁S₅O₃₉ | | |
| Compound 7 | {[Bi₆O₅(OH)₃(NO₃)₃]₂}⁴⁺•4(anthraquinone- | 58.9 | 60.2 |
| | 2-sulfonate anion) | | |
| | Bi₁₂C₅₆N₆H₃₄S₄O₅₄ | | |
| Compound 8 | [Bi₉O₈(OH)₆]⁵⁺•5(anthraquinone-2- | 53.6 | 51.4 |
| | sulfonate anion) | | |
| | Bi₉C₇₀H₄₁S₅O₃₉ | | |
| Compound 9 | {[Bi₆O₅(OH)₃(NO₃)₃]₂}⁴⁺•4(4-azidobenzoate | 66.6 | 67.7 |
| | anion) | | |
| | Bi₁₂C₂₈N₁₈H₂₂O₄₂ | | |
| Compound 10 | [Bi₉O₈(OH)₆]⁵⁺•5(4-azidobenzoate anion) | 65.0 | 66.8 |
| | Bi₉C₃₅N₁₅H₂₆O₂₄ | | |
| Compound 11 | {[Bi₆O₅(OH)₃(NO₃)₃]₂}⁴⁺•4(6-maleimide | 63.8 | 70.5 |
| | hexanoate anion) | | |
| | Bi₁₂C₄₀N₁₀H₅₄O₅₀ | | |
| Compound 12 | [Bi₉O₈(OH)₆]⁵⁺•5(6-maleimide hexanoate | 60.8 | 61.3 |
| | anion) | | |
| | Bi₉C₅₀N₅H₆₆O₃₄ | | |
| Compound 13 | {[Bi₆O₅(OH)₃(NO₃)₃]₂}⁴⁺•4(anthraquinone- | 58.9 | 52.1 |
| | 1-sulfonate anion) | | |
| | Bi₁₂C₅₆N₆H₃₄S₄O₅₄ | | |
| Compound 14 | {[Bi₆O₅(OH)₃(NO₃)₃]₂}⁴⁺•4(2-((9,10- | 52.8 | 53.3 |
| | dihydro-4-(methylamino)-9-10-dioxo-1- | | |
| | anthracenyl)amino)-5-methyl | | |
| | benzenesulfonate anion) | | |
| | Bi₁₂C₈₈N₁₄H₇₄S₄O₅₄ | | |
| Compound 15 | {[Bi₆O₅(OH)₃(NO₃)₃]₂}⁴⁺•4(naphthoquinone- | 59.2 | 68.1 |
| | 2-diazido-5-sulfonate anion) | | |
| | Bi₁₂C₄₀N₁₄H₂₆S₄O₅₀ | | |
| Compound 16 | {[Bi₆O₅(OH)₃(NO₃)₃]₂}⁴⁺•4(4-n-octyl | 60.7 | 57.1 |
| | benzenesulfonate anion) | | |
| | Bi₁₂C₅₆N₆H₉₀S₄O₄₆ | | |
| Compound 17 | {[Bi₆O₅(OH)₃(NO₃)₃]₂}⁴⁺•4(4-n- | 61.9 | 64.8 |
| | octyloxybenzoate anion) | | |
| | Bi₁₂C₆₀N₆H₉₀O₄₆ | | |
| Compound 18 | {[Bi₆O₅(OH)₃(NO₃)₃]₂}⁴⁺•4(ketoprofen | 61.2 | 58.5 |
| | anion) | | |
| | Bi₁₂C₆₄N₆H₅₈O₄₆ | | |
| Compound 19 | {[Bi₆O₅(OH)₃(NO₃)₃]₂}⁴⁺•4[mono (2- | 63.5 | 70.7 |
| | acryloyloxyethyl)succinate anion] | | |
| | Bi₁₂C₃₆N₆H₅₀O₅₈ | | |
| Compound 20 | [Bi₆O₅(OH)₃(NO₃)₃]₂}⁴⁺•4[3- | 64.8 | 72.5 |
| | (acryloyloxy) propane-1-sulfonate anion] | | |
| | Bi₁₂C₂₄N₆H₄₂S₄O₅₄ | | |

(Preparation of Radiation-Sensitive Resist Composition)

Radiation-Sensitive Resist Compositions 1 to 20 were prepared by dissolving 0.2 g of Compounds 1 to 20, respectively, in 4.8 g of the organic solvent shown in Table 2.

(Preparation of Resist Film)

Radiation-Sensitive Resist Compositions 1 to 20 obtained above were each coated onto a 4-inch silicon wafer by a spin coater. Then, prebaking was performed at 130° C. for 120 seconds using a hot plate, to yield a resist film having a dry film thickness of 40 nm.

(Exposure of Resist Film to Radiation and Sensitivity Evaluation)

The sensitivity of the radiation-sensitive resist composition was evaluated by irradiating an electron beam (E-beam) which has a high correlation with extreme ultraviolet rays (EUV). Using an electron beam lithography system (ELS-7500, manufactured by ELIONIX Inc., acceleration voltage: 50 kV), two sites on the resist film, each having a size of 250 μm×250 μm, were irradiated with an electron beam at a varying radiation dose. The radiation dose was 500 μC/cm² and 5,000 μC/cm². After radiation, the resist film was developed at 25° C. for 1 minute and rinsed with methanol. After rinsing, measurements of film thickness at two radiated sites were made, and sensitivity evaluation was performed. In the table below, for the negative type, ⊚ indicates when a film having a film thickness of 20 nm or more was obtained at both sites irradiated at 500 μC/cm² and 5,000 μC/cm²; ∘ indicates when a film having a film thickness of 20 nm or more was obtained only at the site irradiated at 5,000 μC/cm²; and x indicates when a film having a film thickness of 20 nm or more was obtained at neither of the irradiated sites. For the positive type, ⊚ indicates when no film remained at both sites irradiated at 500 μC/cm² and 5,000 μC/cm²; ∘ indicates when no film remained only at the site irradiated at 5,000 μC/cm²; and x indicates when a film remained at both irradiated sites.

In particular, materials included in the solvents and developers disclosed in Table 2 are as follows:

NMP: N-Methyl-pyrrolidone

DMSO: Dimethyl sulfoxide

Mixed solvent 1: Mixed solvent of N-methylpyrrolidone and propylene glycol monomethyl ether in weight ratio of 1:3

Mixed solvent 2: Mixed solvent of N-methylpyrrolidone and propylene glycol monomethyl ether in weight ratio of 1:9

Mixed solvent 3: TMAH 2.38 mass % in aqueous solution (alkaline developer).

TABLE 2

| | | | Radiation- | | |
|---|---|---|---|---|---|
| | | | sensitive | | |
| | | | resist | | Sensitivity |
| | Compound | Solvent | composition | Developer | evaluation |
| Example 1 | Compound | NMP | Composition | Mixed | Negative |
| | 3 | | 3 | solvent 2 | type ⊚ |
| Example 2 | Compound | NMP | Composition | DMSO | Negative |
| | 4 | | 4 | | type ⊚ |
| Example 3 | Compound | NMP | Composition | Mixed | Negative |
| | 5 | | 5 | solvent 1 | type ◯ |
| Example 4 | Compound | NMP | Composition | Mixed | Negative |
| | 6 | | 6 | solvent 1 | type ◯ |
| Example 5 | Compound | NMP | Composition | Mixed | Negative |
| | 7 | | 7 | solvent 1 | type ⊚ |
| Example 6 | Compound | NMP | Composition | Mixed | Negative |
| | 8 | | 8 | solvent 1 | type ⊚ |
| Example 7 | Compound | DMSO | Composition | DMSO | Negative |
| | 9 | | 9 | | type ⊚ |
| Example 8 | Compound | DMSO | Composition | DMSO | Negative |
| | 10 | | 10 | | type ⊚ |
| Example 9 | Compound | DMSO | Composition | DMSO | Negative |
| | 11 | | 11 | | type ◯ |
| Example 10 | Compound | DMSO | Composition | DMSO | Negative |
| | 12 | | 12 | | type ◯ |
| Example 11 | Compound | NMP | Composition | Mixed | Negative |
| | 13 | | 13 | solvent 1 | type ⊚ |
| Example 12 | Compound | DMSO | Composition | DMSO | Negative |
| | 14 | | 14 | | type ◯ |
| Example 13 | Compound | DMSO | Composition | Mixed | Positive |
| | 15 | | 15 | solvent 3 | type ◯ |
| Example 14 | Compound | NMP | Composition | Mixed | Negative |
| | 16 | | 16 | solvent 2 | type ◯ |
| Example 15 | Compound | Toluene | Composition | Toluene | Negative |
| | 17 | | 17 | | type ◯ |
| Example 16 | Compound | NMP | Composition | Mixed | Negative |
| | 18 | | 18 | solvent 2 | type ◯ |
| Example 17 | Compound | DMSO | Composition | DMSO | Negative |
| | 19 | | 19 | | type ⊚ |
| Example 18 | Compound | DMSO | Composition | DMSO | Negative |
| | 20 | | 20 | | type ⊚ |
| Comparative | Compound | DMSO | Composition | DMSO | Negative |
| Example 1 | 1 | | 1 | | type X |
| Comparative | Compound | NMP | Composition | Mixed | Negative |
| Example 2 | 2 | | 2 | solvent 2 | type X |

As shown in Table 2 above, the radiation-sensitive resist compositions of Examples 1 to 18, containing Compound 3 to 20, respectively, showed good sensitivity to the electron beam. Meanwhile, the radiation-sensitive resist compositions of Examples 1 and 2, containing Compounds 1 and 2, respectively, failed to produce sufficient sensitivity even at a radiation dose of 5,000 μC/cm².

(Comparison of EUV Absorption Coefficients)

In Jpn. J. Appl. Phys. Vol. 38(1999) pp. 7109-7113, the entire contents of which are herein incorporated by reference, calculation methods and calculated results for linear absorption coefficients of resist polymers in EUV regions are disclosed. Table 3 shows absorption coefficients of the resist polymers (poly(4-hydroxystyrene), polymethylmethacrylate, Polymer 1, and Polymer 7) disclosed in Table 1 and Table 2 of the above publication, (Comparative Examples 3 to 6) and absorption coefficients in the EUV region of Compound 3 and Compound 10 obtained above (Examples 19 and 20).

Absorbance coefficients of Compound 3 and Compound 10 may be calculated by the following method. The density of the resist films of Radiation-Sensitive Resist Compositions 3 and 10 was measured by X-ray reflectometry employing an X-ray diffractometer (manufactured by Rigaku Co., Ltd., SmartLab™), and the result showed that the density of Compound 3 was 3.9, and the density of Compound 10 was 4.0. Hereinbelow, as described in the method disclosed in Jpn. J. Appl. Phys. Vol. 38 (1999) pp. 7109-7113, the EUV absorbance coefficient per 1 micron (μm) of film thickness of the resist film was calculated from the density of film obtained, and the absorbance coefficient of each atom disclosed in B. L. Henke, E. M. Gullikson, and J. C. Davis. X-ray interactions; photoabsorption, scattering, transmission, and reflection at E=50-30000 eV, Z=1-92, Atomic Data and Nuclear Data Tables Vol. 54 (no. 2), 181-342 (July 1993), the entire contents of which are herein incorporated by reference.

TABLE 3

| | | EUV absorbance |
|---|---|---|
| | | coefficient per |
| | | 1 μm |
| | | film thickness |
| | Composition | of resist film |
| Example 19 | Compound 3 | 21.1 |
| Example 20 | Compound 10 | 21.2 |
| Comparative | Poly(4-hydroxystyrene) | 3.80 |
| Example 3 | | |
| Comparative | Polymethyl methacrylate | 4.80 |
| Example 4 | | |
| Comparative | Polymer 1 | 4.19 |
| Example 5 | | |
| Comparative | Polymer 7 | 3.71 |
| Example 6 | | |

Here, the description of the materials used in Comparative Examples 3 to 6 is as follows:

Poly(4-hydroxystyrene): Representative polymer of chemically amplified resists

Polymethylmethacrylate: Representative polymer of resists for electron beams

Polymer 1: Methacryl polymer having an acid-labile group, representative polymer of chemically amplified resists

Polymer 7: Cresol novolac polymer, a typical polymer of positive type resists

As can be seen in Table 3, it may be found that Compounds 3 and 10 of Examples 19 and 20 have an EUV absorbance coefficient that is about 4 times or greater of the absorbance coefficient of typical resist polymer materials indicated in Comparative Examples 3 to 6.

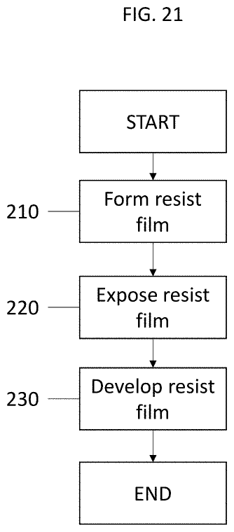

FIG. 21 illustrates a method of forming a pattern on a substrate.

Referring to FIG. 29, at 210 a resist film may be deposited onto the substrate. The resist film may be formed by coating the above-described radiation-resistant resist composition onto the substrate.

At 220, the resist film may be exposed. The exposure may be performed by one or more of irradiation of extreme ultraviolet (EUV) radiation or an electron beam (EB).

At 230, the resist film may be developed.

Various example embodiments may provide a radiation-sensitive resist composition which has improved radiation (EUV in particular) absorption properties and thus has improved sensitivity and/or resolution.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

It should be understood that various example embodiments described herein should be considered in a descriptive sense only and not for purposes of limitation. Descriptions of features or aspects within each embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. An ionic salt comprising:
a polyvalent ion (a) having a metal cluster structure or a metal oxide cluster structure; and
an organic ion (b),
wherein the polyvalent ion (a) comprises one or more metal atoms selected from the group consisting of tin, indium, antimony, tellurium, and bismuth, and
the organic ion (b) is at least one selected from the group consisting of: a carboxylate anion having 4 or more carbon atoms; a sulfonate anion having 4 or more carbon atoms; a phosphonate anion having 4 or more carbon atoms; a phenoxide anion having 6 or more carbon atoms; an iodonium cation having 4 or more carbon atoms; a sulfonium cation having 4 or more carbon atoms; an ammonium cation having 4 or more carbon atoms; and a pyridinium cation having 5 or more carbon atoms.

2. The ionic salt of claim 1, wherein the polyvalent ion (a) comprises one or more metal atoms selected from the group consisting of indium, antimony, tellurium, and bismuth.

3. The ionic salt of claim 1, wherein a total number of metal atoms in the polyvalent ion (a) is greater than or equal to 4 and is less than or equal to 30.

4. The ionic salt of claim 1, wherein with respect to 100 at % of a total number of metal atoms in the polyvalent ion (a), a content of one or more metal atoms selected from the group consisting of tin, indium, antimony, tellurium, and bismuth is 50 at % or more.

5. The ionic salt of claim 1, wherein the polyvalent ion (a) has a molecular weight of about 600 or more to about 9,000 or less.

6. The ionic salt of claim 1, wherein the polyvalent ion (a) has a valency of 3 or more.

7. The ionic salt of claim 1, wherein the polyvalent ion (a) has an average diameter of about 0.5 nm or more and about 10 nm or less.

8. The ionic salt of claim 1, wherein the polyvalent ion (a) is at least one selected from the group consisting of [Sn₈W₁₈O₆₆]⁸⁻, [Sn₄W₂Si₂O₆₈]¹⁴⁻, [Sn₃W₁₈Si₂O₆₈]¹⁴⁻, [Sn₃W₁₈P₂O₆₈]¹²⁻, [SnW₁₂H₂O₄₂]⁸⁻, [W₂₈Te₁₀O₁₈]²⁸⁻, [W₁₈Te₂Cu₃H₆O₆₉]¹⁰⁻, [W₂₀Te₄H₂O₈₀]²²⁻, [W₂₈Te₉O₁₁₂]²⁴⁻, [W₅₈Te₂H₁₀O₁₉₈]²⁶⁻, [W₁₈TeH₃O₆₃]⁵⁻, [W₁₈TeH₃O₆₂]⁷⁻, [W₆TeO₂₄]⁶⁻, [W₁₇Te₂O₆₁]¹²⁻, [W₁₅TeNaO₅₄]¹³⁻, [Te₄C₈H₂₀]²⁺, [InW₁₁PH₄O₄₀]⁴⁻, [InW₁₁SiH₄O₄₀]⁵⁻, [InW₃O₄(C₂H₄COO)₈]²²⁻, [Sb₂I₉]⁻, [{(4-chlorophenyl)Sb}₁₂Na₂H₉O₃₀]⁻, [(SbW₉O₃₃)₂{Nb(C₂H₄)}₂]¹²⁻, [Mo₂Te₁₂]⁶⁺, [NbTe₁₀]³⁻, [Ru₆(Te₂)₇(CO)₁₂]²⁻, [(SbW₉O₃₃)₂{Nb(C₂H₄)}₂]¹²⁻, [MoTe₈O]²⁺, [Bi₆(CH₃OH)₂(NO₃)₃(OH₂)₂(Sha_{-1H})₁₂]²⁺, [Bi₆O₄(OH)₄(H₂O)₆]²⁺, [Bi₆O₄(OH)₄(NO₃)₅(H₂O)]⁺, [Bi₆O₄OH(cit)₃(H₂O)₃]³⁻, [Pr₄Sb₁₂O₁₈Cl₁₇]⁵⁻, [Pr₄Sb₁₂O₁₈Cl₁₄(1,3-bdc)]⁴⁻, [Pr₄Sb₁₂O₁₈Cl₁₁(1,4-bdc)₂]³⁻, [OIn₆(taci_{-3H})₄]⁴⁺, [In₃Te₇]⁵⁻, {[Bi₆O₅(OH)₃(NO₃)₃]₂}⁴⁺, [Bi₉O₈(OH)₆]⁵⁺, and [Bi₉O₈(OC₂H₄)₆]⁵⁺.

9. The ionic salt of claim 1, wherein the organic ion (b) is at least one selected from the group consisting of: a carboxylate anion having 4 or more carbon atoms; a sulfonate anion having 4 or more carbon atoms; a phosphonate anion having 4 or more carbon atoms; a phenoxide anion having 6 or more carbon atoms; an iodonium cation having 4 or more carbon atoms; a sulfonium cation having 4 or more carbon atoms; an ammonium cation having 4 or more carbon atoms and having at least one functional group selected from the group consisting of a carbon-carbon multiple bond-containing group, a carbonyl group-containing group, an oxime group, an oxime ester group, a halogenated alkyl group, a phosphorus-containing group, a diazo group, and an azide group; and a pyridinium cation having 5 or more carbon atoms and having at least one functional group selected from the group consisting of a carbon-carbon multiple bond-containing group, a carbonyl group-containing group, an oxime group, an oxime ester group, a halogenated alkyl group, a phosphorus-containing group, a diazo group, and an azide group.

10. The ionic salt of claim 1, wherein the organic ion (b) has at least one functional group selected from the group consisting of a vinyl group, a stilbene group, an azide group, a diazoalkane group, a diaziridine group, a cinnamate group, an anthracene group, an anthraquinone group, a maleimide group, a styrylpyridine group, an arylsulfonium group, an aryliodonium group, and a phenyl ester group.

11. The ionic salt of claim 1, wherein the organic ion (b) is a monovalent ion.

12. The ionic salt of claim 1, wherein the organic ion (b) is at least one selected from the group consisting of a 4-azidobenzoate anion unsubstituted or substituted with a substituent, a cinnamate anion unsubstituted or substituted with a substituent, a nicotinate anion unsubstituted or substituted with a substituent, a ketoprofen anion unsubstituted or substituted with a substituent, a 6-maleimide caproate anion (6-maleimide hexanoate anion) unsubstituted or substituted with a substituent, a 4-naphthoquinone diazide sulfonate anion unsubstituted or substituted with a substituent, a 5-naphthoquinone diazide sulfonate anion unsubstituted or substituted with a substituent, a 6-naphthoquinone diazide sulfonate anion unsubstituted or substituted with a substituent, an anthraquinone-1-sulfonate anion unsubstituted or substituted with a substituent, an anthraquinone-2-sulfonate anion unsubstituted or substituted with a substituent, a 9,10-dimethoxyanthracene-2-sulfonate anion unsubstituted or substituted with a substituent, a 4-[4-(dimethylamino)styryl]-1-methylpyridinium cation unsubstituted or substituted with a substituent, diphenyliodonium cation unsubstituted or substituted with a substituent, a triphenyl sulfonium cation unsubstituted or substituted with a substituent, an N-octadecyl-4-stilbazole cation (N-octadecyl-4-styrylpyridinium cation) unsubstituted or substituted with a substituent, a mono(2-acryloyloxyethyl)succinate anion unsubstituted or substituted with a substituent, and a 3-(acryloyloxy)propane-1-sulfonate anion unsubstituted or substituted with a substituent.

13. The ionic salt of claim 1, wherein the organic ion (b) has a molecular weight of about 50 or more and about 5,000 or less.

14. The ionic salt of claim 1, wherein the ionic salt has a total molecular weight of about 650 or more and about 30,000 or less.

15. The ionic salt of claim 1, wherein a ratio of a molecular weight of the polyvalent ion (a) to a total molecular weight of the organic ion (b) [molecular weight of (a)/total molecular weight of (b)] is about 0.3 or more and about 30 or less.

16. The ionic salt of claim 1, wherein the polyvalent ion (a) is cationic, and the organic ion (b) is anionic.

17. A radiation-sensitive resist composition comprising:
the ionic salt of claim 1; and
an organic solvent.

18. The radiation-sensitive resist composition of claim 17, wherein with respect to 100 mass % of a total mass of the radiation-sensitive resist composition, the ionic salt is about 0.5 mass % or more to about 39 mass % or less.

19. A pattern forming method comprising:
forming a resist film by coating the radiation-sensitive resist composition of claim 17 onto a substrate;
exposing the resist film; and
developing the exposed resist film.

20. The pattern forming method of claim 19, wherein the exposing is performed by one or more of irradiation of extreme ultraviolet (EUV) radiation or an electron beam (EB).
